(19) United States
(12) Patent Application Publication
(10) Pub. No.: US 2025/0306555 A1
(43) Pub. Date: Oct. 2, 2025

(54) USER-INTERACTABLE DESIGN FOR MANUFACTURABILITY OF SHEET METAL

(71) Applicant: OSH Cut INC, Spanish Fork, UT (US)

(72) Inventors: Caleb Hunter Chamberlain, Payson, UT (US); Eric Russell Mansfield, Spanish Fork, UT (US)

(21) Appl. No.: 18/756,607

(22) Filed: Jun. 27, 2024

Related U.S. Application Data
(60) Provisional application No. 63/570,423, filed on Mar. 27, 2024.

(51) Int. Cl. G05B 19/042; B23Q 15/20

(52) U.S. Cl. CPC G05B 19/0423; B23Q 15/20; G05B 2219/23258

(57) ABSTRACT

A system may be configurable to (i) access an input file submitted by a user and comprising a representation of a sheet metal part; (ii) cause presentation of a user interface that enables user selection or modification of bend radius or bend angle for one or more bends of the sheet metal part; (iii) generate a modified sheet metal part based on user selection or modification of the bend radius or bend angle; (iv) determine manufacturability of the modified sheet metal part; (v) when the modified sheet metal part is manufacturable with particular manufacturing configurations available to one or more manufacturing facilities: (a) automatically determine or update a price of manufacturing the modified sheet metal part based on the particular manufacturing configurations; (b) cause presentation of the price of manufacturing the modified sheet metal part within the user interface; and (c) selectively enable order placement functionality within the user interface.

### CROSS-REFERENCE TO RELATED APPLICATIONS

This application claims priority to U.S. Provisional Application No. 63/570,423, filed on Mar. 27, 2024, and entitled “USER-INTERACTABLE DESIGN FOR MANUFACTURABILITY OF METAL TUBING”, the entirety of which is incorporated herein by reference for all purposes.

### BACKGROUND

The manufacturing of sheet metal parts often includes sheet metal bending, which involves the deformation of metal sheets along a straight axis to achieve a desired angle or shape. Sheet metal bending is performed to create components that are integral to a wide variety of industries, including automotive, aerospace, electronics, construction, and others. Bending operations are executed using specialized machinery, such as press brakes, which apply force to the metal sheet at a specific location, causing it to bend. The complexity of the bend can range from simple, single-angle bends to complex sequences requiring precise control over angle, direction, and sequence.

The subject matter claimed herein is not limited to embodiments that solve any challenges or that operate only in environments such as those described above. Rather, this background is only provided to illustrate one exemplary technology area where some embodiments described herein may be practiced.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 illustrates an example user interface display for obtaining an input file representing a custom metal part, in accordance with implementations of the disclosed subject matter.

FIG. 2 illustrates an example user interface display that conceptually depicts the determination of manufacturability of a custom sheet metal part obtained according to FIG. 1, in accordance with implementations of the disclosed subject matter.

FIG. 3 illustrates an example user interface display that includes an indication of manufacturability of the custom sheet metal part, in accordance with implementations of the disclosed subject matter.

FIGS. 4, 5, and 6 illustrate example user interface displays that include a flat pattern of the custom sheet metal part and that also provide an indication of manufacturability of the custom sheet metal part, in accordance with implementations of the disclosed subject matter.

FIGS. 7 and 8 illustrate example user interface displays that include a manufacturing simulation of the custom sheet metal part and that also provide an indication of manufacturability of the custom sheet metal part, in accordance with implementations of the disclosed subject matter.

FIG. 9 illustrates an example user interface display for obtaining a material selection for manufacture of the custom sheet metal part, in accordance with implementations of the disclosed subject matter.

FIG. 10 illustrates an example user interface display that includes a flat pattern of the custom sheet metal part and that also provide an indication of manufacturability of the custom sheet metal part, in accordance with implementations of the disclosed subject matter.

FIGS. 11 and 12 illustrate example user interface displays that include a flat pattern of the custom sheet metal part and that include sheet metal part characteristics, in accordance with implementations of the disclosed subject matter.

FIG. 13 illustrates an example user interface display that includes a modified custom sheet metal part based on user modifications to the sheet metal part characteristics, in accordance with implementations of the disclosed subject matter.

FIG. 14 illustrates an example user interface display that includes the custom sheet metal part without modifications, in accordance with implementations of the disclosed subject matter.

FIGS. 15, 16, and 17 illustrate example user interface displays that include a manufacturing simulation of the modified custom sheet metal part, in accordance with implementations of the disclosed subject matter.

FIG. 18 illustrates an example user interface display that includes order placement functionality, in accordance with implementations of the disclosed subject matter.

FIG. 19 illustrates an example user interface display that includes a bend sequence configuration for manufacturing a custom sheet metal part, in accordance with implementations of the disclosed subject matter.

FIGS. 20 and 21 illustrate example user interface displays that include a back gauge configuration for manufacturing a custom sheet metal part, in accordance with implementations of the disclosed subject matter.

FIG. 22 illustrates an example user interface display that includes a manufacturing simulation of a custom sheet metal part, in accordance with implementations of the disclosed subject matter.

FIG. 23 depicts example components of a system that may comprise or be configurable to perform various embodiments.

### DETAILED DESCRIPTION

Disclosed embodiments are directed to systems and methods for facilitating user-interactable design for manufacturability of sheet metal.

As noted above, sheet metal bending is performed to manufacture sheet metal parts in numerous industries. Many custom metal fabrication shops offer sheet metal manufacturing services that include sheet metal bending. However, normal workflows adopted by many custom metal fabrication shops are associated with numerous challenges. For instance, to receive custom sheet metal bending services, a customer typically provides a model or schematic of the sheet metal part to be manufactured to a custom fabrication shop. The custom fabrication shop then performs a manufacturability analysis to determine whether the custom fabrication shop has the capability to manufacture the desired sheet metal part (e.g., to determine whether the proper material, machinery, tooling, etc. are available). For example, a laser cutting programmer of a custom fabrication shop may be tasked with determining whether appropriate blanks can be cut to manufacture a desired part, and, subsequently, a press brake programmer may be tasked with determining whether available press brake machinery and tooling can make the bends necessary to produce the desired part, etc. If the part is not manufacturable, the custom fabrication shop can communicate such issues to the customer, which can prompt the customer to redesign the desired part to conform to the manufacturing capabilities of the custom fabrication shop.

Conventional manufacturability analyses, as described above, are often time-intensive, labor-intensive, and costly (e.g., due to the specialized labor required for such analyses) for both custom fabrication shops and their customers. Custom fabrication shops can thus be very selective about which customers to engage with on such manufacturability analyses, which can limit the ability of new customers to secure custom metal part manufacturing services.

At least some disclosed embodiments are directed to systems, methods, and techniques for facilitating user-interactable design for manufacturability of sheet metal parts. At least some disclosed embodiments can provide a user-interactable interface (e.g., a web-accessible interface or device application interface) that allows customers to submit a custom part (e.g., via upload) to trigger automatic, server-based design for manufacturability (DFM) processes to be performed on the custom part. For sheet metal parts, the DFM processes can include flattening the custom part and performing virtual bending operations on the flattened part. The virtual bending operations can be performed in accordance with manufacturing configurations available to a specific custom fabrication shop/facility (e.g., press brake machinery availability and capability, press brake tooling available, sheet metal material availability and dimensions, etc.).

Based on the automated DFM processes, a manufacturability indicator can be presented on the user interface, which can indicate whether the custom part is manufacturable by the specific custom fabrication shop (or set of shops/facilities). The user interface can present part characteristics that are user-modifiable, which can enable users to adjust design aspects of the custom part to achieve or approach manufacturability. For sheet metal parts, the part characteristics can include bend radius, bend angle, bend direction, and/or other characteristics. In some implementations, the user interface can be configured to provide a manufacturing simulation that simulates manufacturing of the custom part (e.g., visually simulating bending operations), and the simulation can emphasize aspects of the custom part (or manufacturing process therefor) that cause failure of the manufacturability test/analysis (e.g., collisions with tooling).

Based on user modifications to the part characteristics, a modified part may be generated (e.g., using server resources), and automated DFM processes may be performed (e.g., using server resources) to determine whether the modified part is manufacturable. The manufacturability indicator may be updated based on the updated DFM processes performed for the modified part, which can beneficially allow users to make iterative modifications to their part to achieve or approach manufacturability (without costly back-and-forth between personnel of the custom fabrication shop and the customer). In some instances, the user interface can simultaneously display or selectively toggle between displaying the original custom part (e.g., as originally provided by the customer and on which initial DFM processing was performed) and the modified part to allow users to visually inspect differences in characteristics (e.g., differences in material thickness, bend radius, etc.).

In some instances, the user interface can present manufacturing configurations that are available to the specific custom fabrication shop, which can also enable users to adjust manufacturing configurations to achieve or approach manufacturability for their custom part. For sheet metal parts, example manufacturing configurations can include punch configurations, die configurations, back gauge configurations, bend sequence configurations, machine selection configurations, part orientation (during bending), etc.

When the custom part (or modified part generated based on user modifications) is determined to be manufacturable (based on automated DFM processes), the user interface can be configured to selectively enable price calculation/updating and/or order placement functionality, which can allow users to place an order that triggers manufacturing of the custom part (or modified part) by the specific custom fabrication shop (or manufacturing facility). Such functionality can significantly reduce the burden associated with acquiring (and providing) price quotes for custom metal fabrication, which can improve accessibility and experiences.

Having just described some of the various high-level features and benefits associated with the disclosed subject matter, attention will now be directed to the Figures, which illustrate various conceptual representations, architectures, methods, and/or supporting illustrations related to the disclosed embodiments.

Various Figures described hereinbelow show example user interface displays, which can be displayed on one or more devices/systems pursuant to execution of program instructions associated with an application (whether locally stored or accessed via a web browser or other mechanism). As used herein, a “user interface” can refer to a point of interaction between a user and a digital device that displays content (e.g., “user interface content” or “user interface display”) associated with such an application and/or can receive user input for interacting with the displayed content (e.g., a display screen with a controller such as a mouse and/or keyboard, a desktop or laptop computer, a touch screen, a wearable device, etc.). The content associated with the application that is displayed on the user interface can comprise one or more pages or workflow steps/presentations, amongst which the user can navigate via control input provided via the user interface within an interactive session.

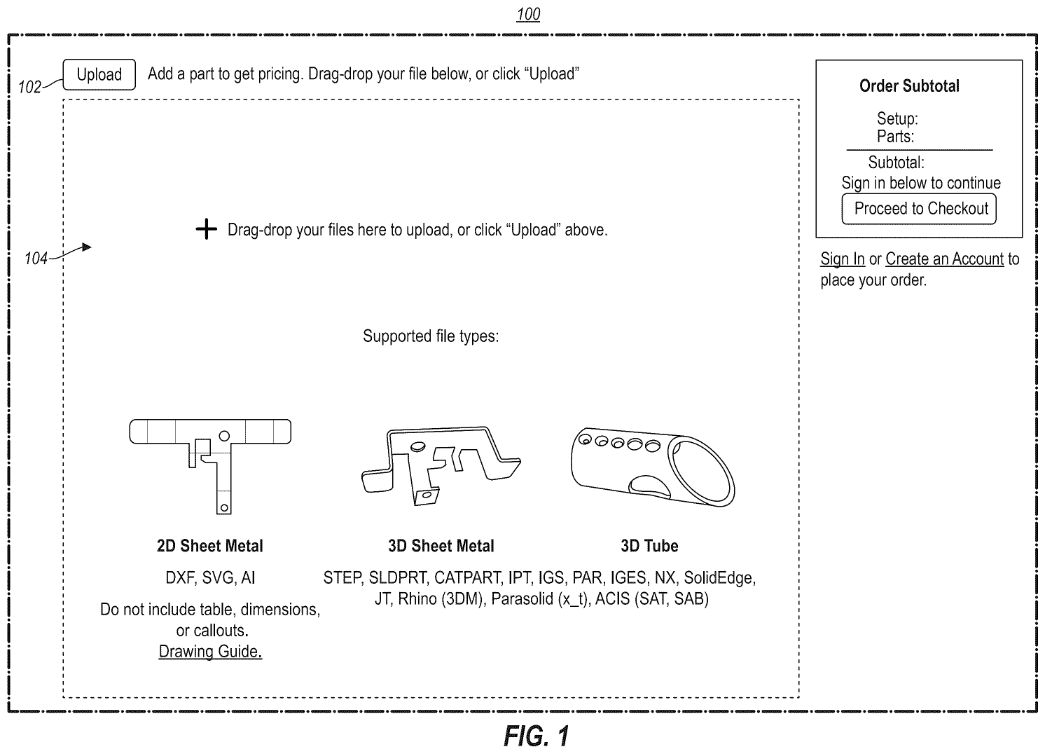

FIG. 1 illustrates an example user interface display 100 for obtaining an input file representing a custom metal part. For instance, the user interface display 100 includes an upload element 102, which may be selectable by users to enable submission of an input file. The user interface display 100 of FIG. 1 also includes a drag-drop space 104 whereon users may drag and drop an input file for submission. The input file to be submitted can be locally stored on a user device displaying the user interface display 100. The input file can take on various forms, such as a 2D drawing file (e.g., DFX, SVG, AI, and/or others) or a 3D model file (e.g., STEP, SLDPRT, CATPART, IPT, IGS, PAR, IGES, NX, SolidEdge, JT, 3DM, x_t, SAT, SAB, and/or others). The input file submitted by the user (e.g., interacting with the user interface display 100) can include a representation of a sheet metal part (e.g., a custom sheet metal part).

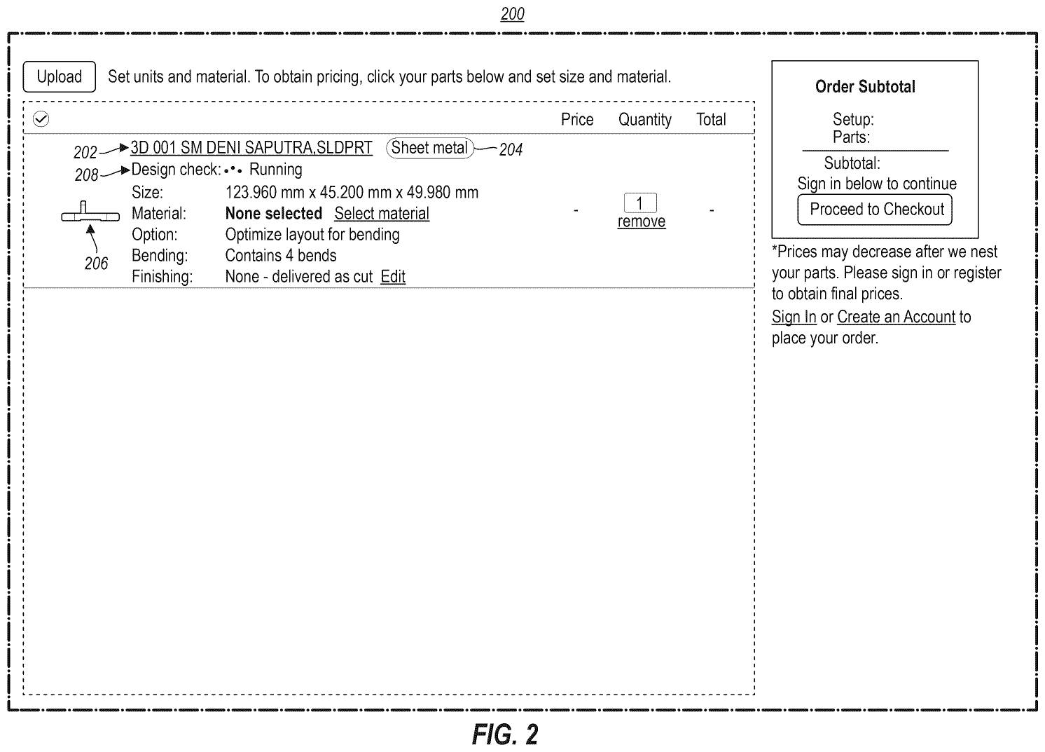

FIG. 2 illustrates an example user interface display 200 that conceptually depicts the determination of manufacturability of the sheet metal part represented by the input file discussed above with reference to FIG. 1. FIG. 2 conceptually depicts the input file 202 (by reference to its name) as well as a type label 204 that states “sheet metal”. The input file 202 can be preprocessed (e.g., using server and/or local resources) to determine whether the input file 202 includes a representation of a sheet metal part (or another type of part). The type label 204 can be defined and/or presented based on the outcome of such preprocessing.

FIG. 2 also conceptually depicts the sheet metal part 206 represented by the input file 202 (by showing a thumbnail depiction thereof). FIG. 2 also conceptually depicts the performance of the determination of manufacturability (e.g., “DFM processing”) by displaying a design check element 208, which includes a “Running” label indicating that the DFM processing for the sheet metal part 206 is underway/ongoing. In some implementations, such as where the input file 202 comprises a 3D model file, the DFM processing for a sheet metal part (e.g., sheet metal part 206) includes generating a flat pattern based on sheet metal part 206 represented by the input file 202. The flat pattern can be generated by applying virtual inverse bending operations to the sheet metal part 206. Where the input file 202 comprises a 2D drawing file, the flat pattern can be generated directly from the input file 202 (one or more preprocessing operations may be applied).

After acquisition of a flat pattern for the sheet metal part 206 represented by the input file 202, the DFM processing can include applying one or more virtual bending operations to the flat pattern. The virtual bending operation(s) can be based on manufacturing configurations available to one or more specific manufacturing facilities (or one or more “designated” manufacturing facilities) that can receive an order for custom sheet metal part fabrication arising from the user's interaction with the user interface (e.g., based on the user's interaction with a web application that underlies the various example user interface displays shown/described herein). In this regard, the manufacturing configurations used for the virtual bending operation(s) can be based on inventory-specific and/or machine-specific data associated with the designated manufacturing facility or facilities, which can be dynamically updated to reflect current conditions (e.g., to reflect changes in material, tooling, or machine availability, etc.). Example manufacturing conditions specific to one or more manufacturing facilities that can predicate virtual bending operations for DFM processing can include available machinery (e.g., available press brake machine types), available die configurations (e.g., die type, die size, etc.), available punch configurations (e.g., punch type, punch size, etc.), available back gauge configurations (e.g., positions assumable by one or more back gauges of one or more press brake machines), and/or others. In some instances, the DFM processing for determining whether a sheet metal part (e.g., sheet metal part 206) is manufacturable can depend on part-specific manufacturing configurations, such as potential bend sequences for manufacturing the sheet metal part (e.g., even considering ordering of partial bends), potential part orientations for performing the bends to manufacture the sheet metal part, etc.

In some implementations, the DFM processing to determine whether the sheet metal part 206 is manufacturable is performed using one or more server resources. The DFM processing can involve iteratively applying different sets of virtual bending operations to the flat pattern for the sheet metal part 206 that each use different manufacturing configurations (e.g., capturing variations in machinery used, tooling used, back gauge configurations used, bend sequences used, part orientations used, etc.), which can allow a system to determine one or more manufacturing configurations for manufacturing the sheet metal part 206 that avoid, reduce, or minimize potential errors (e.g., collisions, lack of flange support, etc.).

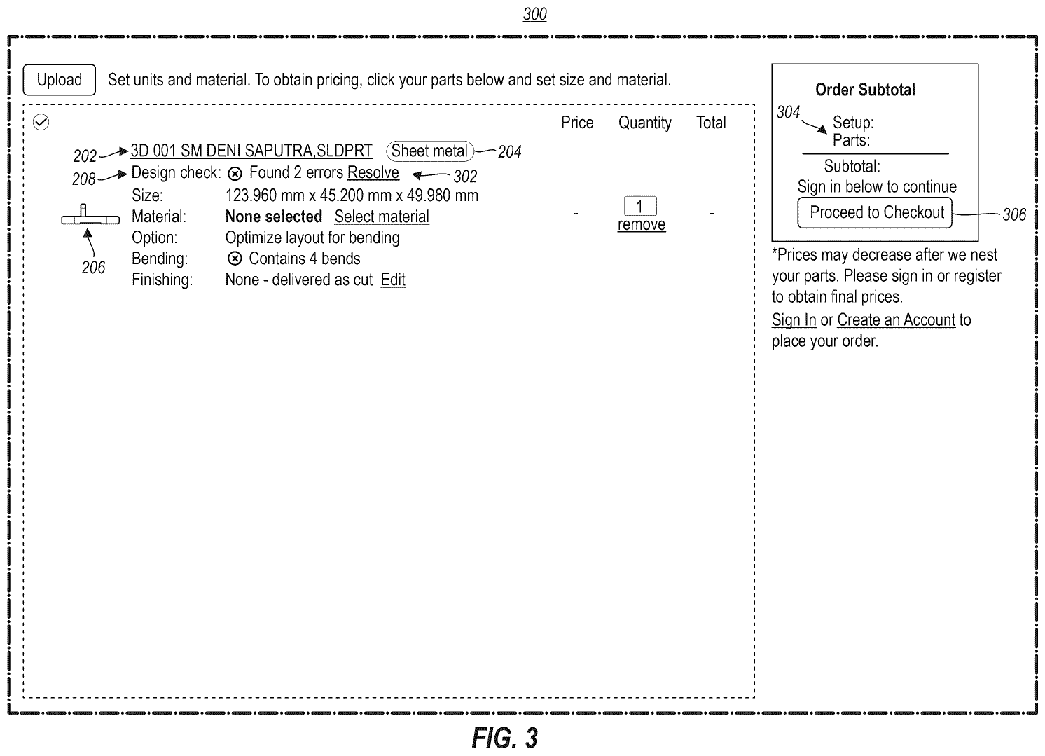

FIG. 3 illustrates an example user interface display 300 that includes a manufacturability indicator 302 (or an “indication of manufacturability”) for the sheet metal part 206 represented by the input file 202 that was subjected to DFM processing as described above. In the example of FIG. 3, the manufacturability indicator 302 indicates (for illustrative purposes) that one or more manufacturing errors exist (by stating “Found 2 errors”), which can indicate that the sheet metal part 206 in its current form is not manufacturable by the one or more designated manufacturing facilities whose available manufacturing configurations were used to perform the DFM processing. As will be described in more detail hereinafter, a manufacturability indicator can take on various forms, provide various types of information (e.g., problem regions, warnings, recommended modifications), and/or be presented in conjunction with various other user interface display elements.

FIG. 3 furthermore illustrates a price region 304 and a checkout element 306. While the manufacturability indicator 302 indicates that the sheet metal part 206 is not manufacturable, the system(s) providing the user interface display 300 (e.g., a server and/or a user device executing a web-based application) can refrain from populating the price region 304 with price information and/or can refrain from enabling checkout or order placement functionality via the checkout element 306. In some implementations, the system(s) providing the user interface display 300 can selectively generate or update price information and/or selectively enable order placement functionality when it is determined that a subject sheet metal part is manufacturable by a designated manufacturing facility.

The user interface display 300 of FIG. 3 illustrates the depiction of the input file 202 as a selectable element, which can be selected to trigger presentation of additional user interface displays for assessing or modifying various characteristics of the sheet metal part 206 (and/or flat patterns or modified sheet metal parts generated based on the sheet metal part 206).

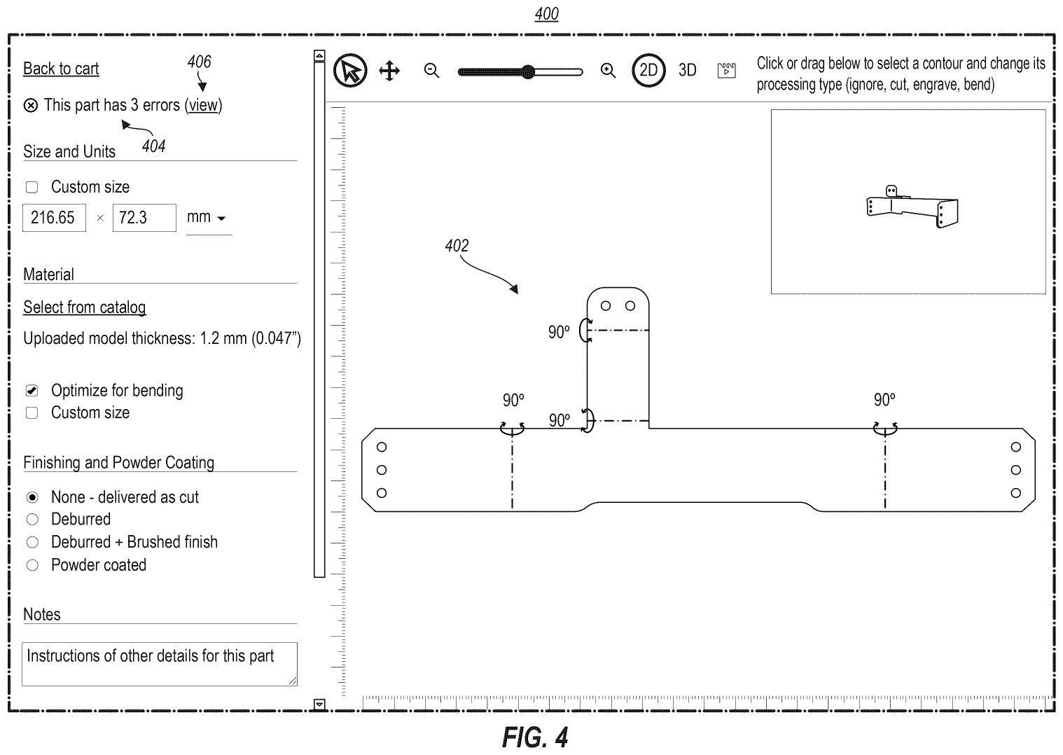

FIGS. 4, 5, and 6 illustrate example user interface displays 400, 500, and 600, respectively, that include a flat pattern 402 of the sheet metal part 206. Each of the user interface displays 400, 500, and 600 also includes a respective indication of manufacturability for the sheet metal part 206. For instance, user interface display 400 includes a manufacturability indicator 404 that indicates (for illustrative purposes) that various errors exist with respect to manufacturing of the sheet metal part 206 (and therefore that the sheet metal part 206 is not manufacturable by the designated manufacturing facility/facilities). The manufacturability indicator 404 includes a selectable element 406 that can allow users to drill down on specific aspects of the errors detected during the DFM process.

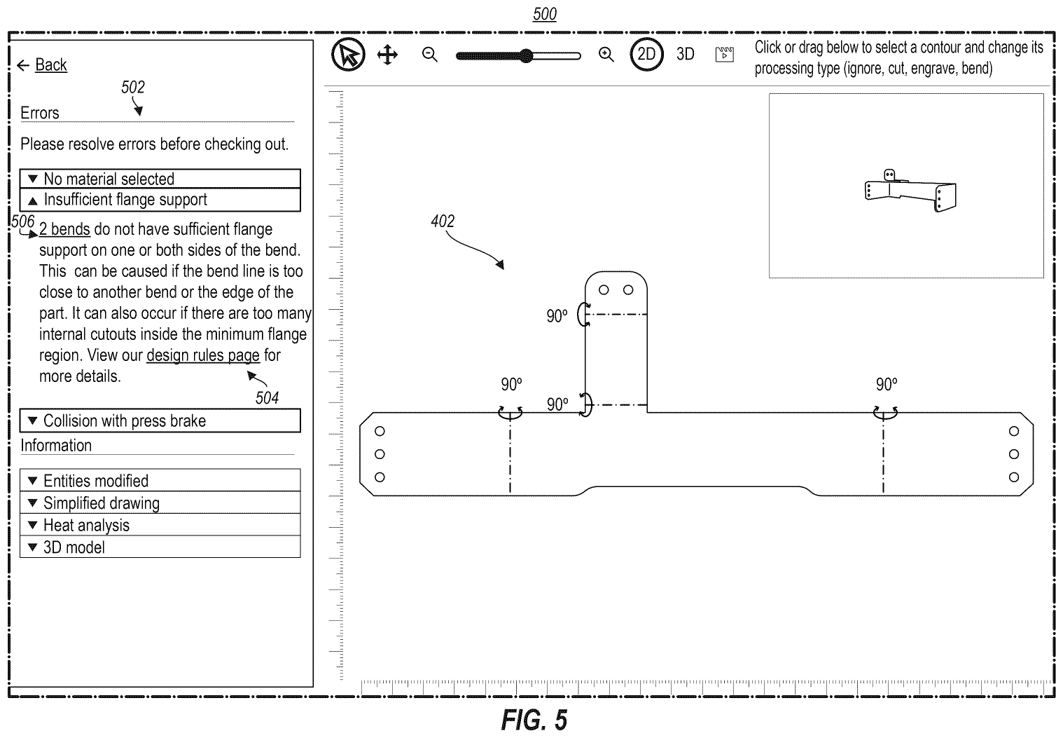

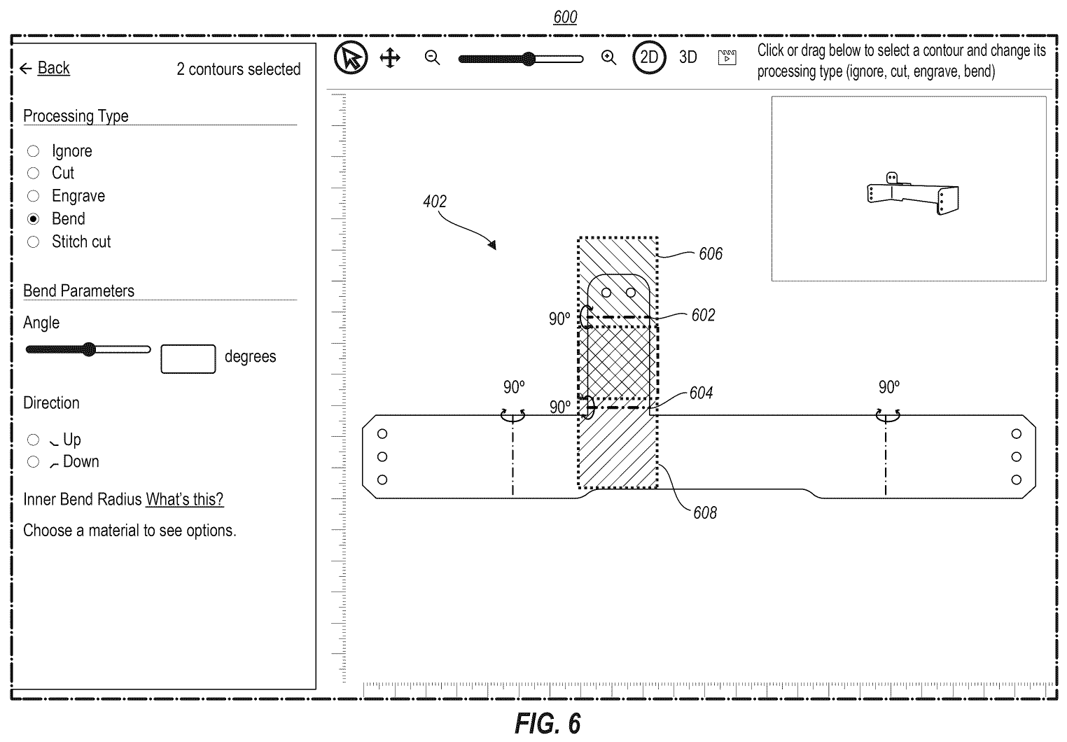

User interface display 500 can be displayed after selection of the selectable element 406 of user interface display 400. In the example shown in FIG. 5, the user interface display 500 includes a manufacturability indicator 502 that provides more granular detail related to the errors detected based on the DFM process. For instance, the manufacturability indicator 502 of the user interface display 500 indicates (for illustrative purposes) that no material has been selected, insufficient flange support has been detected for one or more bends, and collision with the press brake has been detected for one or more bends. The manufacturability indicator 502 illustrates the different manufacturing errors as collapsible banners that provide additional details when opened. In the user interface display 500, the banner related to insufficient flange support is opened, providing the user with a description 504 of the insufficient flange support error detected during DFM processing. For instance, the description 504 includes a selectable element 506 indicating the quantity of bends for which insufficient flange support was detected. Selection of the selectable element 506 can trigger display of the particular bends for which insufficient flange support was detected on the flat pattern 402. User interface display 600 displays the bends 602 and 604 on the flat pattern 402 for which insufficient flange support was detected. Additionally, the user interface display 600 depicts die contact areas 606 and 608 (for bends 602 and 604, respectively) on the user interface display 400. In the example shown in FIG. 6, the die contact areas 606 and 608 are illustrated with line patterns, resulting in a cross pattern on the portions of the die contact areas 606 and 608 that overlap, which can visually indicate to users aspects of the bends 602 and 604 that lack flange support (other forms of visual emphasis/indication may be used). In this regard, a manufacturability indicator can indicate problem regions associated with the sheet metal part 206 (e.g., by showing and/or linking to bends or other regions of the part determined to cause manufacturing failures/issues via the DFM processing).

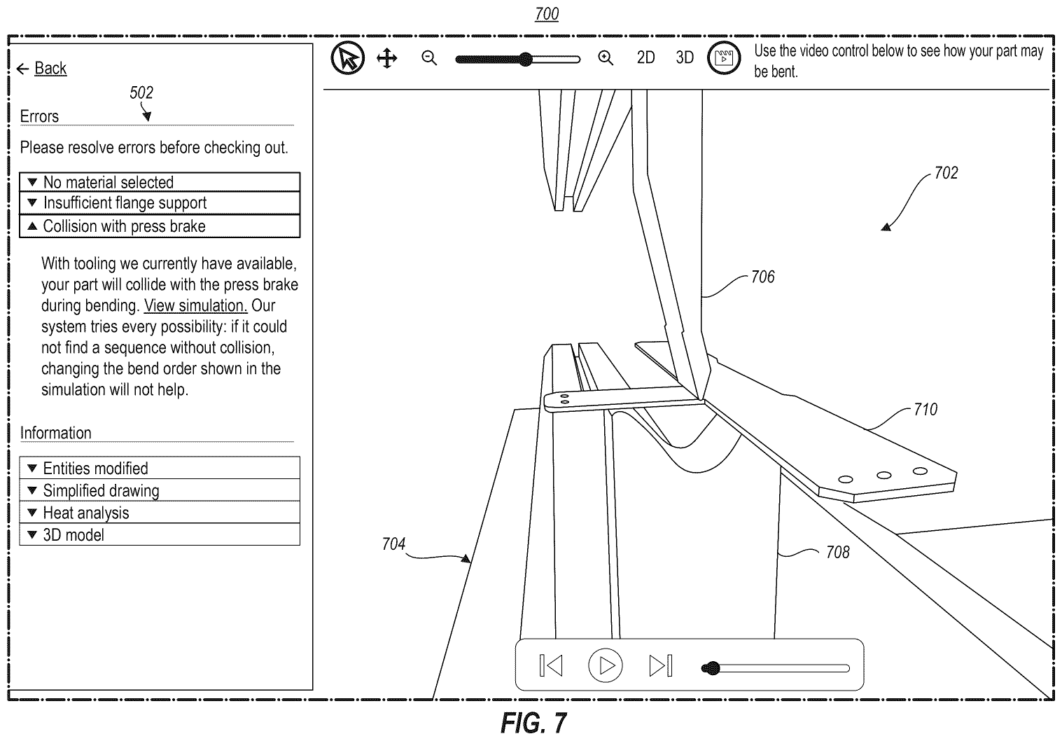

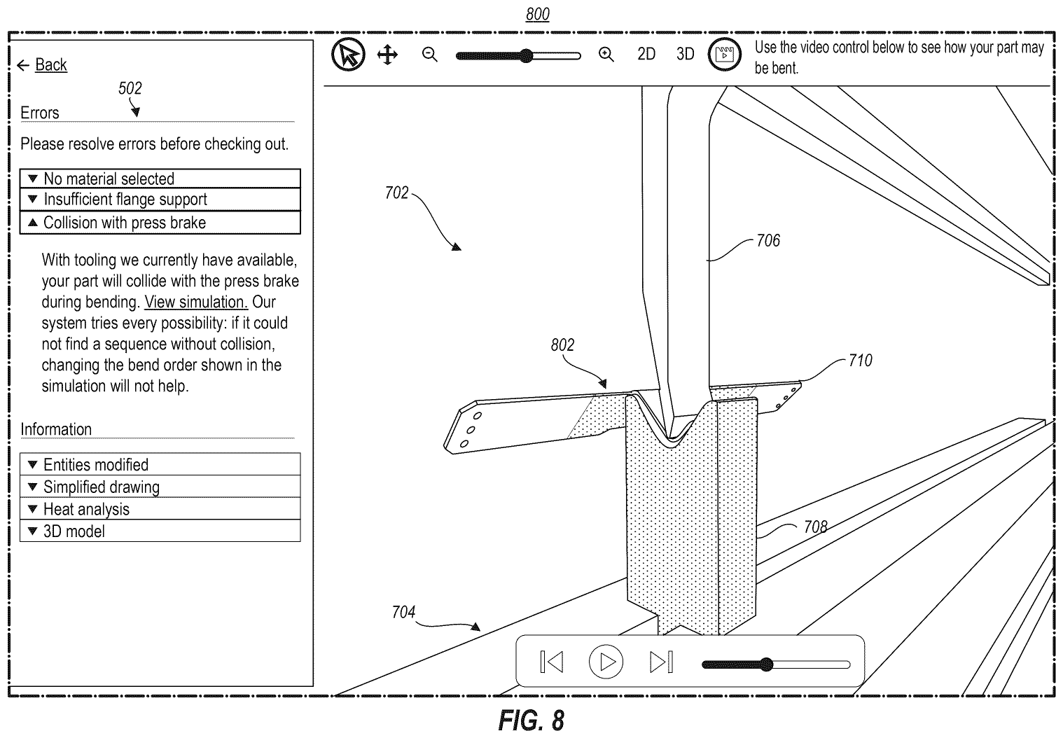

FIGS. 7 and 8 illustrate example user interface displays 700 and 800, respectively, that include a manufacturing simulation 702 for the sheet metal part 206. In the examples of FIGS. 7 and 8, the manufacturing simulation 702 can depict a press brake machine 704 with a punch 706 and a die 708 connected thereto to facilitate bending of a blank 710 that corresponds to the flat pattern 402. In the manufacturing simulation 702, the press brake machine 704 can step through multiple bending steps, visually illustrating movement of the press brake machine 704 to press the blank 710 into contact with the die 708 to facilitate bending of the blank 710 to form a sheet metal part (e.g., corresponding to sheet metal part 206). The specific press brake machine 704, punch 706, die 708, orientation of the blank 710 for bends, bend sequence for bending the blank 710, bend direction for bending the blank 710, etc. used in the various bending operations shown in the manufacturing simulation 702 can be selected based on the DFM processes performed for the sheet metal part 206 as described above. For instance, the manufacturing simulation 702 can visually depict the manufacturing configuration(s) determined to avoid or minimize manufacturing errors after iteratively testing multiple different manufacturing configurations as described above. In some instances, different steps or bend operations of the manufacturing simulation 702 can use different manufacturing configurations (e.g., different machines, punches, dies, etc.).

In the example shown in FIG. 7, the user interface display 700 includes the same manufacturability indicator 502 as the user interface display 500 described above with reference to FIG. 5. In the user interface display 700, the error banner of the manufacturability indicator 502 describing collision with the press brake is expanded, providing users with additional information related to this error. FIG. 8 shows the manufacturing simulation 702 showing a subsequent bending operation relative to that shown in FIG. 7. In the user interface display 800, the die 708 and a region 802 of the blank 710 are illustrated with a dot pattern to visually depict the collision with the press brake described in the manufacturability indicator 502 (other forms of highlighting or emphasizing the collisions may be used). Such functionality (i.e., visually depicting collisions or other failures in a manufacturing simulation 702 for manufacturing a sheet metal part 206) can readily communicate to users the problem regions associated with a sheet metal part 206, which can guide user efforts in modifying aspects of the sheet metal part 206.

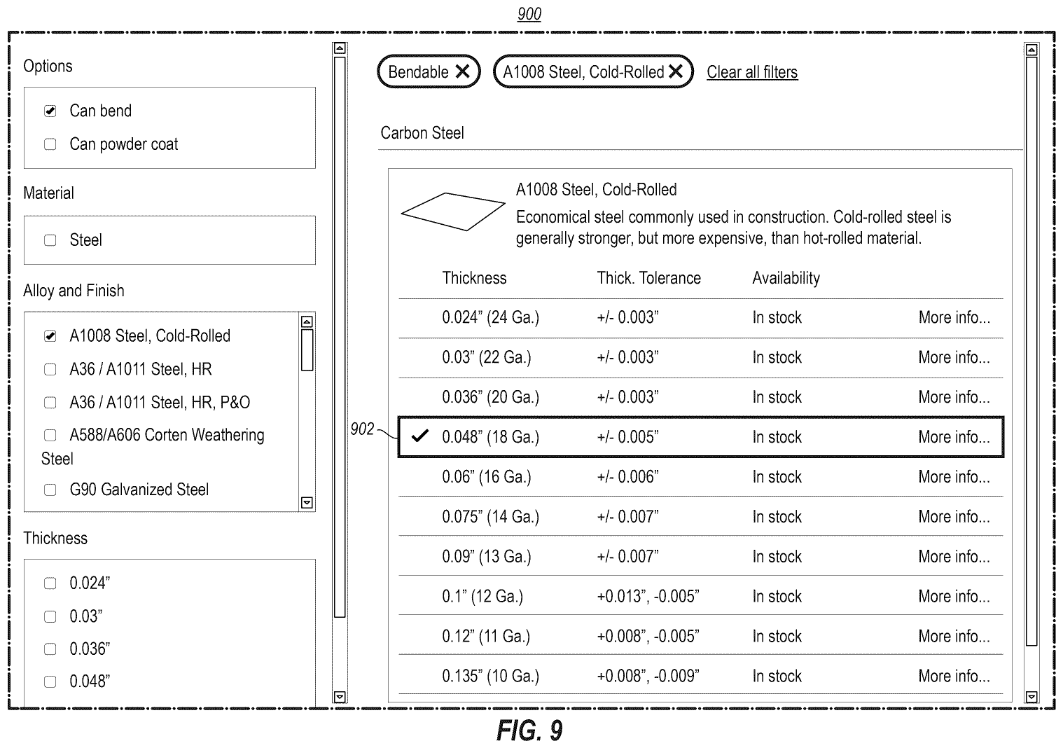

FIG. 9 illustrates an example user interface display 900 for obtaining a material selection for manufacture of the sheet metal part 206. The user interface display 900 can provide various filtering operations, such as whether the material is bendable, thickness, alloy and finish, etc. In the example shown in FIG. 9, a user has provided input designating a selected material 902 (i.e., 18 Ga. A1008 steel, cold-rolled). In some instances, based on the selected material 902, a modified sheet metal part is generated using attributes of the selected material and attributes of the sheet metal part 206 represented by the input file 202. For instance, using the thickness of the selected material 902, a system may generate a modified sheet metal part by adapting bend radii and/or bend locations of the flat pattern 402 based on the sheet metal part 206 represented by the input file 202 in a manner that preserves the overall size of the sheet metal part 206.

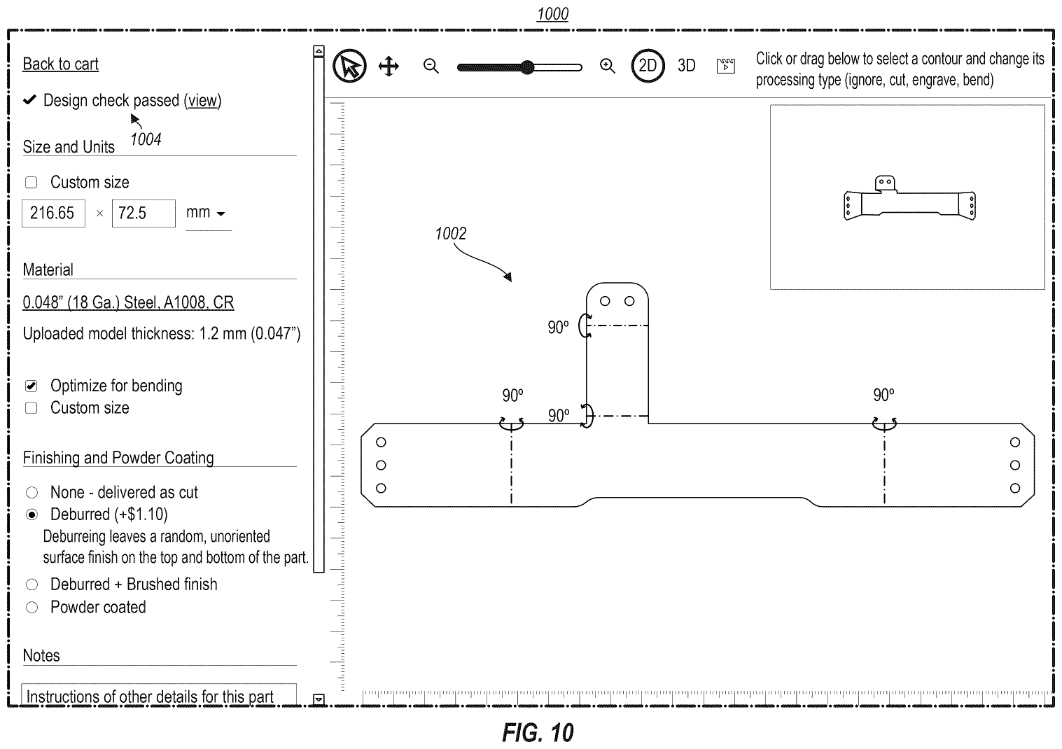

In some implementations, after generating a modified sheet metal part based on a selected material 902 and the sheet metal part 206 as represented in the input file 202, the system may perform DFM processes to determine manufacturability of the modified sheet metal part. FIG. 10 illustrates an example user interface display 1000 that includes a modified flat pattern 1002 for forming a modified sheet metal part (e.g., which may be generated based on the selected material 902 and the sheet metal part 206 as represented by the input file 202, as noted above). DFM processing may be performed using the modified flat pattern 1002, such as by applying virtual bending operations thereto using manufacturing configurations available to one or more designated manufacturing facilities to attempt to form the modified sheet metal part. The user interface display 1000 includes a manufacturability indicator 1004. In the example shown in FIG. 10, based on the DFM processing performed for the modified sheet metal part, the manufacturability indicator 1004 indicates (for illustrative purposes) that the design check is passed (i.e., that the modified sheet metal part is manufacturable by the one or more designated manufacturing facilities).

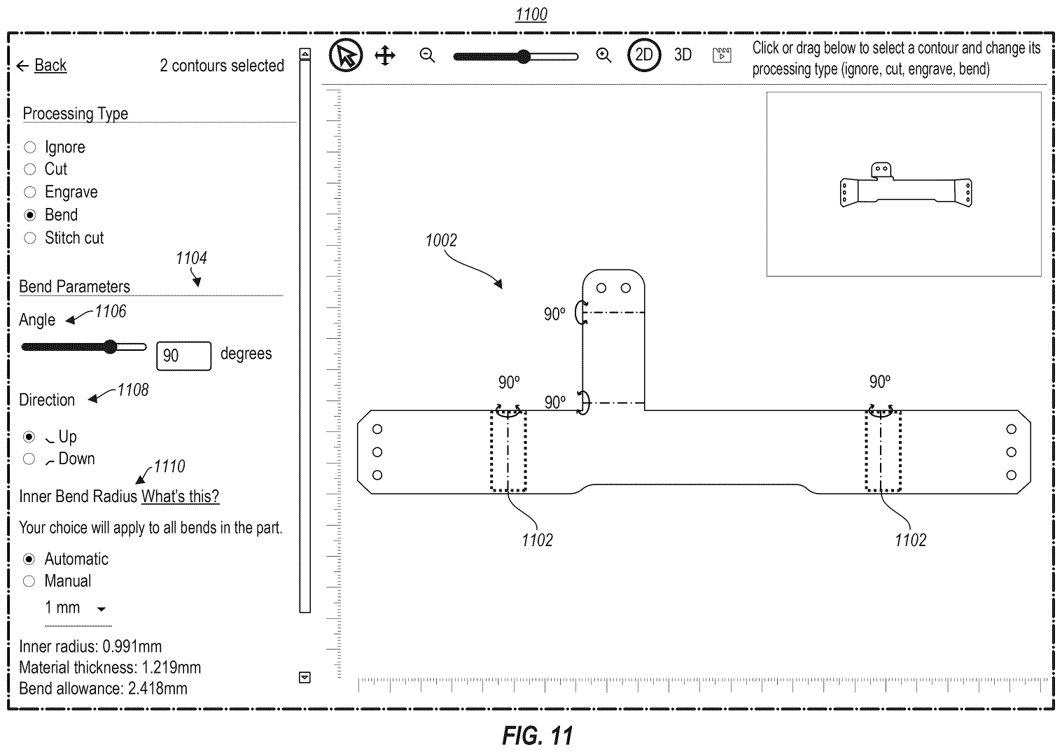

FIG. 11 illustrates an example user interface display 1100 that shows the modified flat pattern 1002 described above. In the example shown in FIG. 11, bends 1102 of the modified flat pattern 1002 bolded (other forms of highlighting or emphasis may be used) to illustrate selection of the bends 1102 (e.g., after detecting user input directed to the bends 1102). As illustrated in FIG. 11, the user interface display 1100 can display characteristics 1104 of the bends 1102 of the modified flat pattern 1002. The characteristics 1104 can include, for example, bend angle 1106, bend direction 1108, bend radius 1110, and/or others. At least some of the characteristics 1104 can be presented in a manner that allows user modification thereto. For instance, the bend angle 1106 is shown with a slide bar and an entry field, permitting user modification to the bend angle 1106 for the bends 1102. As another example, the bend direction 1108 is presented with selectable options (i.e., “Up” or “Down”). As yet another example, the bend radius 1110 is presented with selectable options for selecting “Automatic” determination of the bend radius for the bends 1102 (e.g., based on the selected material 902 and/or the appropriate machine and/or tooling determined via DFM processing) or “Manual” selection of the bend radius 1110 for the bends 1102.

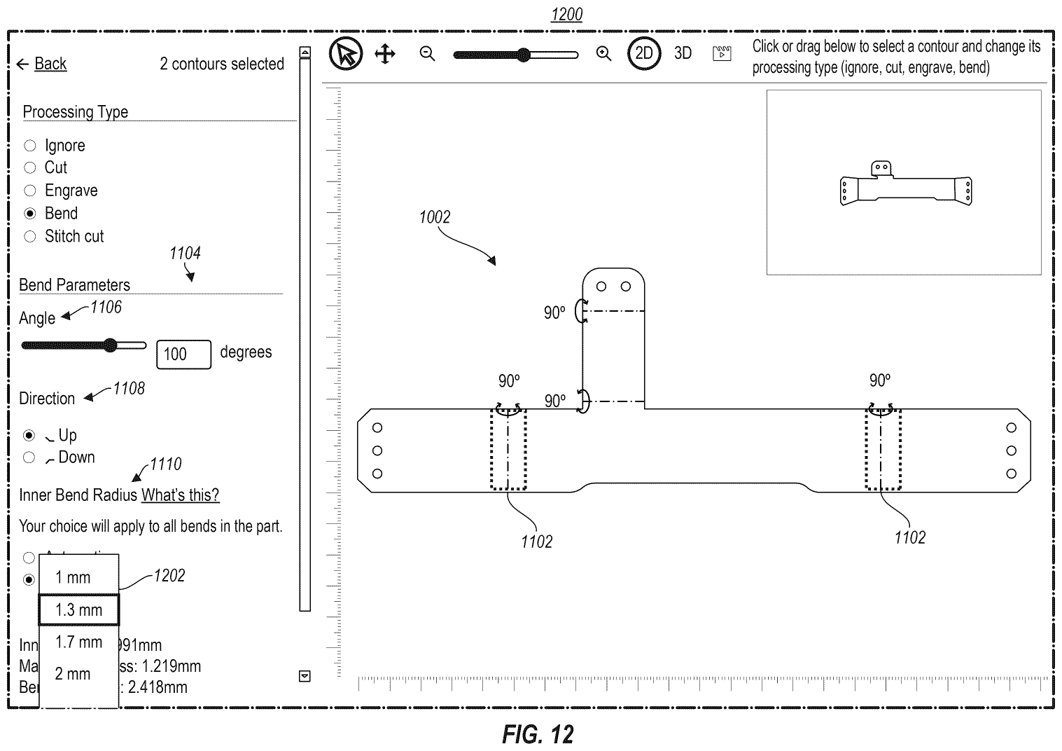

FIG. 12 illustrates an example user interface display 1200 in which characteristics 1104 of the bends 1102 of the modified flat pattern 1002 have been further modified. Specifically, FIG. 12 illustrates an instance in which the bend angle 1106 has been changed to 100 degrees (e.g., from 90 degrees, as shown in FIG. 11) and in which the bend radius 1110 has been changed to 1.3 mm (from 1 mm, as shown in FIG. 11). In the example shown in FIG. 12, manual selection of the bend radius 1110 has been activated, and predetermined bend radius options 1202 for the manually selected bend radius 1110 are presented in the form of a dropdown menu. In some implementations, the predetermined bend radius options 1202 are constrained by at least some of the manufacturing configurations (e.g., die configurations) available to the one or more specific manufacturing facilities (or one or more designated manufacturing facilities) for which an order for manufacture of the sheet metal part 206 (or a modified sheet metal part based thereon) can be sent (e.g., after user interaction with order placement functionality within a user interface as described herein). The predetermined bend radius options 1202 can be additionally or alternatively constrained by the selected material 902.

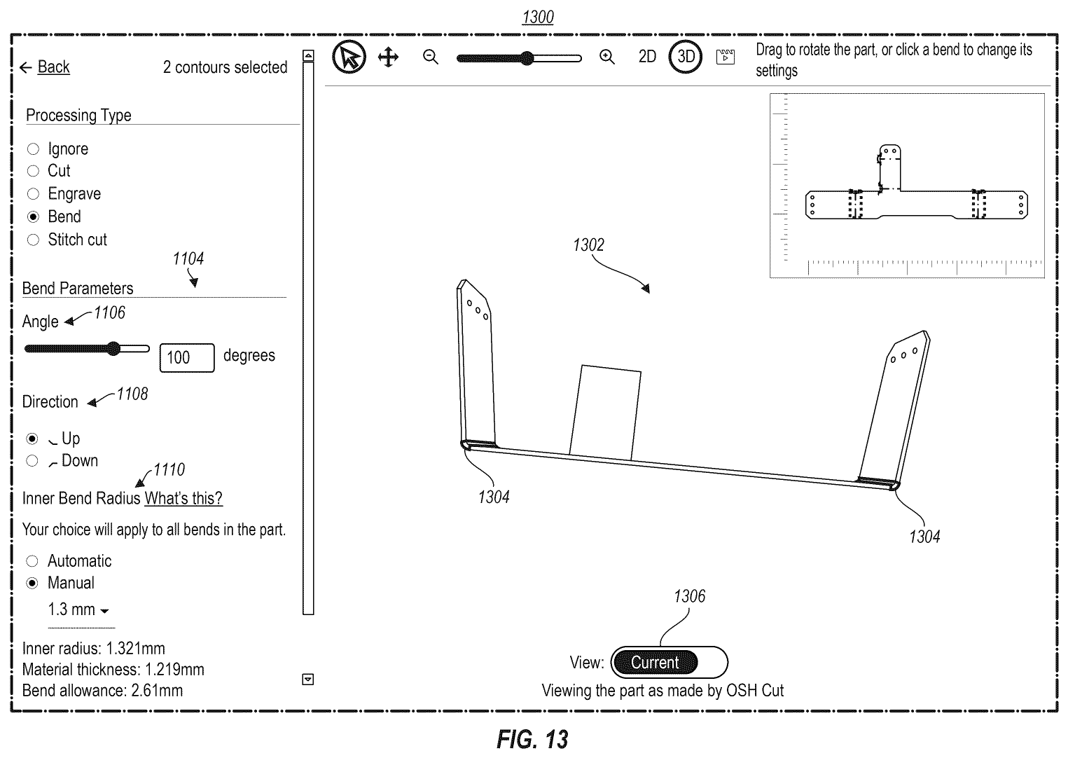

In some instances, a modified sheet metal part (based on the sheet metal part 206 and/or the selected material 902) can be updated or generated further based on user selection or modification of the characteristics 1104 of the various bends of a modified flat pattern 1002 (or flat pattern 402), such as the bend angle 1106 and bend radius 1110 modifications described above for the bends 1102 with reference to FIG. 12. FIG. 13 illustrates an example user interface display 1300 that includes a 3D representation of a modified sheet metal part 1302 that captures the modificatFions to the characteristics 1104 of the bends 1102 discussed above with reference to FIG. 12. For instance, the modified sheet metal part 1302 of the user interface display 1300 includes bends 1304, which correspond to bends 1102 described above. As is shown in the user interface display 1300 of FIG. 13, the bend angle 1106 of the bends 1304 of the modified sheet metal part 1302 is 100 degrees, and the bend radius 1110 of the bends 1304 is 1.3 mm.

The user interface display 1300 of FIG. 13 depicts the bends 1304 of the modified sheet metal part 1302 as highlighted or otherwise emphasized (e.g., with coloring) in 3D form. In some instances, bends may be selectable in different representations of a sheet metal part, and the selection of bends can persist when transitioning between different representations of a sheet metal part or modified sheet metal part (e.g., 3D representation, flat pattern representation, simulation representation, etc.).

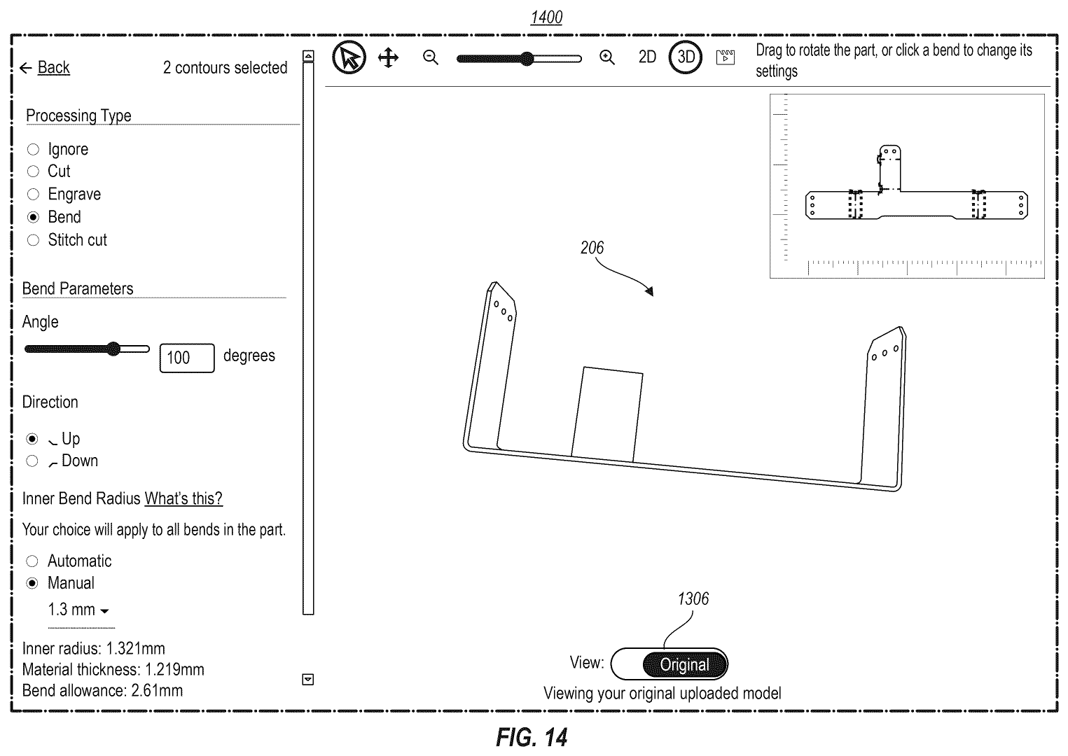

In the example of FIG. 13, the user interface display 1300 includes a toggle element 1306, which can be used to alternate between depicting the original sheet metal part 206 (e.g., according to the input file 202) and the modified sheet metal part 1302. FIG. 14 illustrates an example user interface display 1400 that depicts the sheet metal part 206 in 3D form, which may be triggered by selection of the toggle element 1306 of the user interface display 1300 as described above. Such functionality can enable users to readily ascertain difference between a sheet metal part (e.g., sheet metal part 206) as originally provided (e.g., in the input file 202) and a modified sheet metal part (e.g., modified sheet metal part 1302). Additionally, or alternatively, a system may be configured to simultaneously present a depiction of a sheet metal part as originally uploaded/provided and a depiction of a modified sheet metal part based thereon (e.g., after modifications triggered by material selection and/or user modifications to sheet metal part characteristics).

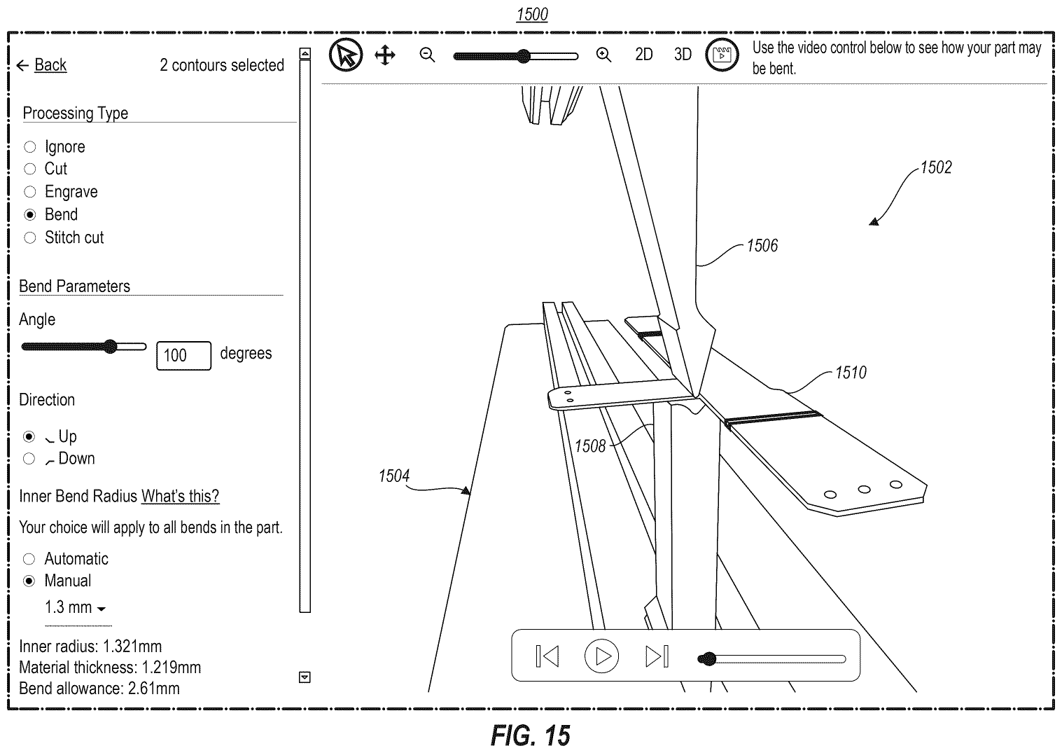

FIGS. 15, 16, and 17 illustrate example user interface displays 1500, 1600, and 1700, respectively, that include a manufacturing simulation 1502 for the modified sheet metal part 1302. The manufacturing simulation 1502 depicts a press brake machine 1504 with a punch 1506 and a die 1508 connected to facilitate bending of a blank 1510 that corresponds to the modified flat pattern 1002. In the manufacturing simulation 1502, multiple bending steps/operations can be shown to visually illustrate movement of the press brake machine 1504 to press the blank 1510 into contact with the die 1508 to facilitate bending of the blank 1510 to form the modified sheet metal part 1302 (e.g., in accordance with the selected material 902, the user-driven modifications to bend characteristics, etc.). The manufacturing simulation 1502 can depict different manufacturing configurations for different bending steps/operations (e.g., different machines, punches, dies, etc.).

The specific manufacturing configurations shown throughout the bending steps/operations of the manufacturing simulation 1502 can be selected based on DFM processes performed for the modified sheet metal part 1302, which may be performed after generation of the modified sheet metal part 1302 (e.g., based on material selections and/or modifications made to bend characteristics as described above with reference to FIGS. 9 through 12). For instance, the manufacturing simulation 1502 can visually depict the manufacturing configuration(s) for different bending operations/steps that are determined to avoid or minimize manufacturing errors after iteratively applying virtual bending operations using multiple different manufacturing configurations available to one or more designated manufacturing facilities, as described above.

In some implementations, aspects of the manufacturing configurations used for the virtual bending operations (e.g., used in the DFM processing) are influenced by the user modifications to or selections of bend characteristics of the modified sheet metal part 1302. For instance, a user selection or modification of the bend angle 1106 can constrain or affect selection of the punch configuration(s) used in the virtual bending operations. As another example, a user selection or modification of the bend radius 1110 can constrain or affect selection of the die configuration(s) used in the virtual bending operations.

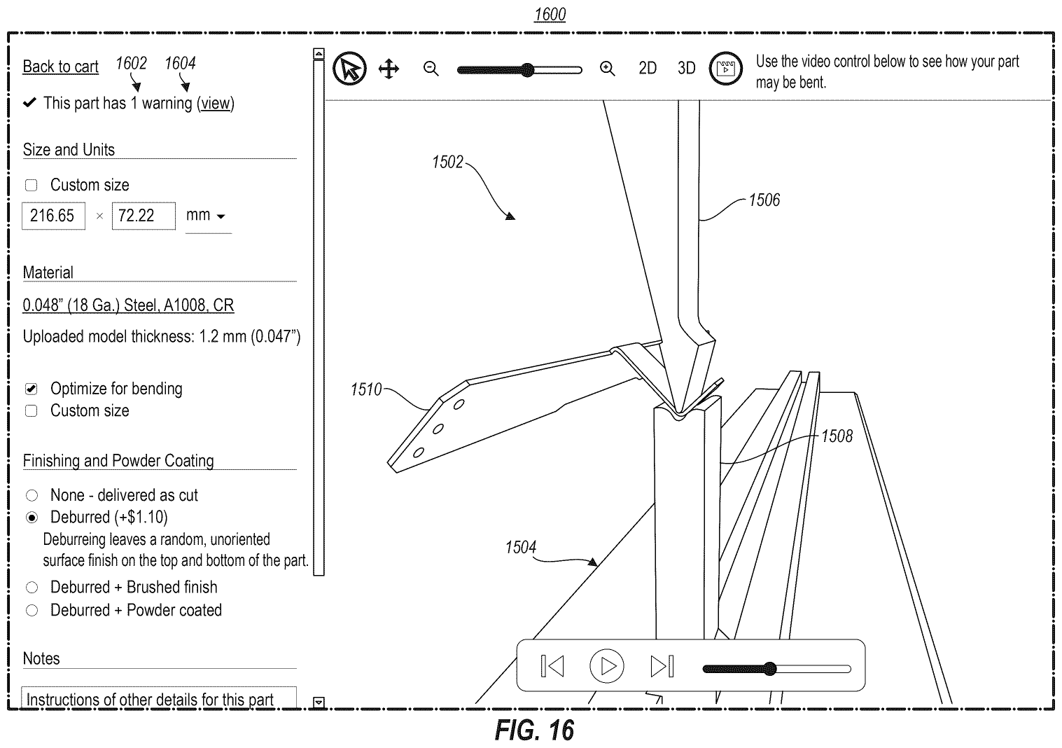

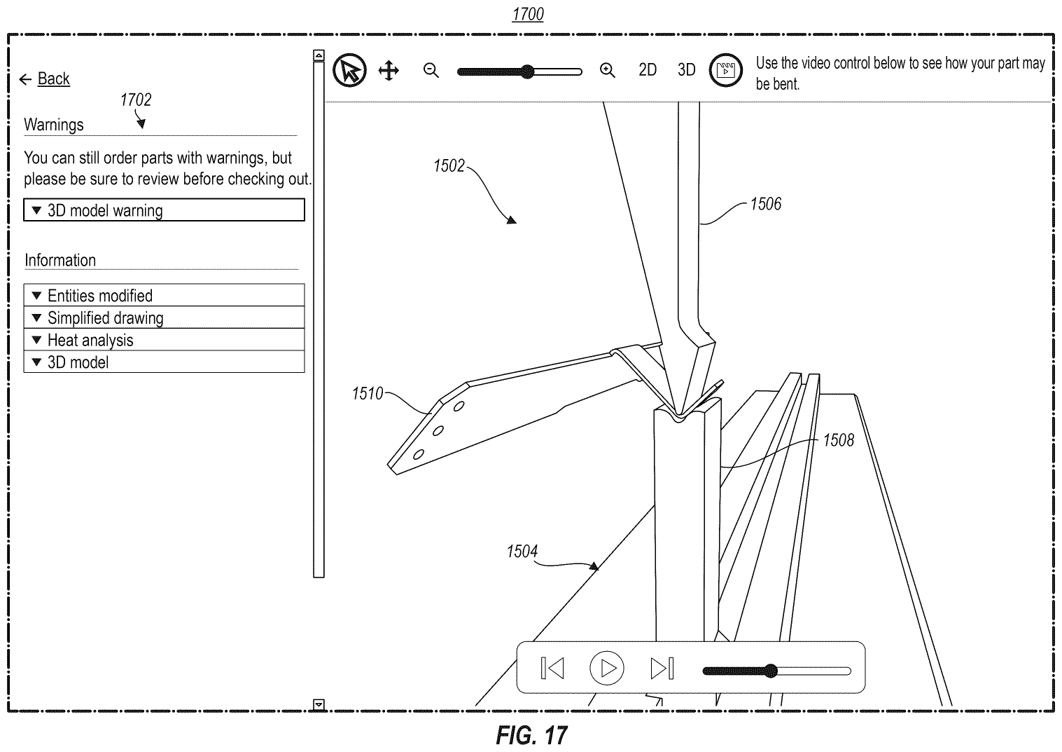

FIG. 16 depicts a manufacturability indicator 1602 indicating whether the modified sheet metal part 1302 is manufacturable based on the DFM processes performed to determine the manufacturability thereof. In the example shown in FIG. 16, the manufacturability indicator 1602 indicates that the part has 1 warning and provides the user with a selectable element 1604 to access more details related to the warning. FIG. 17 illustrates a manufacturability indicator 1702 with additional details related to the warning (e.g., displayed after selection of the selectable element 1604 of FIG. 16). In particular, the manufacturability indicator 1702 of FIG. 17 indicates that parts with warnings are still manufacturable using the manufacturing configurations against which the modified sheet metal part 1302 was tested (and which are available to the designated manufacturing facility/facilities that would receive an order for manufacture of the modified sheet metal part 1302 if placed by the user via the checkout element 306). The manufacturability indicator 1702 also indicates the nature of the warning with a collapsible banner, which indicates that the warning applicable to manufacture of the modified sheet metal part 1302 is a 3D model warning (e.g., warning the user that modifications were made to the sheet metal part 206 as represented in the input file 202 based on selected material 902 and/or user-driven modifications to part characteristics, and that the user should review the changes before moving forward with order placement).

A manufacturability indicator (e.g., manufacturability indicators 1602 or 1702) for a modified sheet metal part 1302 may provide different indications based on the outcomes of the DFM performed for the modified sheet metal part 1302 (e.g., the manufacturability indicator can indicate that the design check has been passed or that no errors or warnings exist, similar to the manufacturability indicator 1004 described above, or the manufacturability indicator can indicate additional or alternative warnings, or the manufacturability indicator can indicate one or more errors, similar to the manufacturability indicators 302, 404, 502, or the manufacturability indicator can indicate a combination of warnings and errors). Furthermore, a manufacturability indicator for a modified sheet metal part 1302 may indicate problem regions for detected warnings or errors (e.g., collision regions, regions that have low or insufficient flange support, etc.) in various presentation modalities (e.g., flat pattern presentations, 3D part presentations, manufacturing simulation presentations, etc.).

In the example manufacturing simulation 1502 shown in FIGS. 15, 16, and 17, the punch 1506 can be selected based on the user selection or modification of the bend angle 1106, as described hereinabove with reference to FIGS. 11 and 12 (e.g., different bend angles can trigger a change in punch configuration to avoid collisions during manufacturing). For instance, and for illustrative purposes, the manufacturing simulation 1502 can comprise a different punch 1506 than the punch 706 shown in conjunction with the manufacturing simulation 702, where different bend angles are used (e.g., compare FIGS. 7 and 15). In some implementations, the die 1508 shown in the manufacturing simulation 1502 can be selected based on user selection or modification of the bend radius 1110, as described hereinabove with reference to FIGS. 11 and 12. For instance, and for illustrative purposes, the manufacturing simulation 1502 can comprise a different die 1508 than the die 708 shown in conjunction with the manufacturing simulation 702, where different bend radii are used (e.g., compare FIGS. 7 and 15).

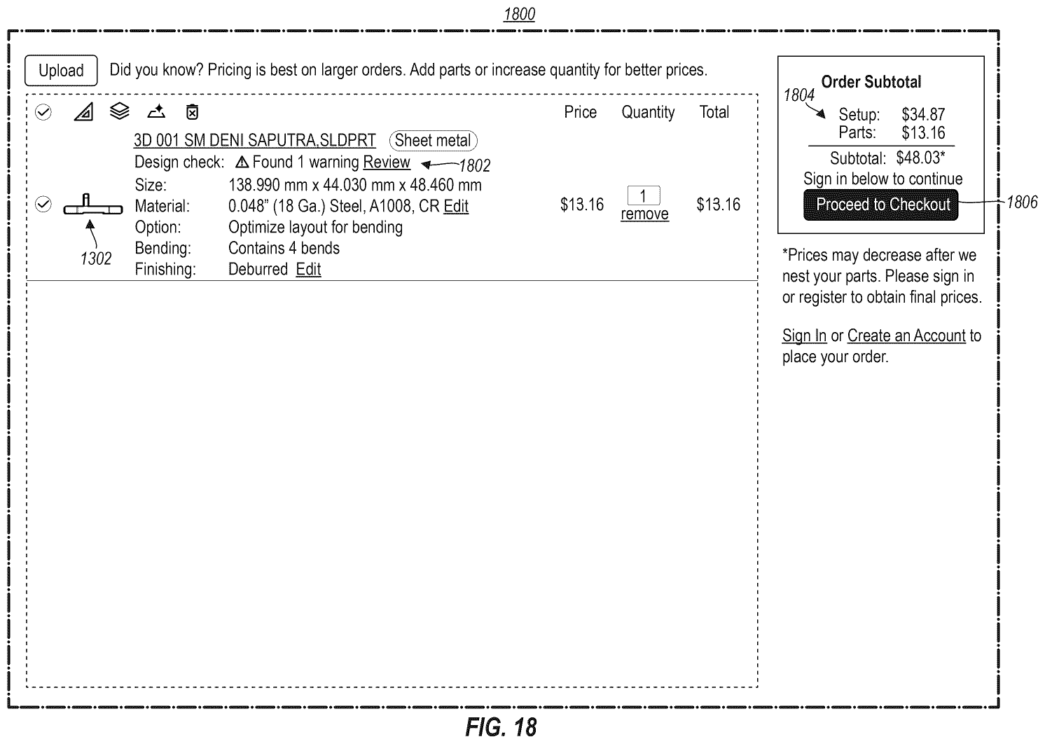

FIG. 18 illustrates an example user interface display 1800 that is similar to the user interface display 300 discussed hereinabove with reference to FIG. 3. For instance, the user interface display 1800 includes a manufacturability indicator 1802 indicating the manufacturability of the modified sheet metal part 1302 as discussed above. The user interface display 1800 also includes a price region 1804 and a checkout element 1806. In contrast with the price region 304 of FIG. 3, the price region 1804 is populated or updated with price information associated with manufacture of the modified sheet metal part 1302, which can be enabled based on the manufacturability indicator 1802 indicating that the modified sheet metal part 1302 is manufacturable (or based on the DFM processing that informs the manufacturability indicator 1802). Similarly, in contrast with the checkout element 306 of FIG. 3, the checkout element 1806 can be enabled based on the manufacturability indicator 1802 indicating that the modified sheet metal part 1302 is manufacturable (or based on the DFM processing that informs the manufacturability indicator 1802), which can enable order placement functionality for users to trigger manufacturing of the modified sheet metal part 1302 by one or more designated manufacturing facilities (e.g., which are configured to receive orders placed via the checkout element 1806).

The price listed in the price region 1804 can be updated based on the particular manufacturing configuration(s) selected for manufacture of the modified sheet metal part 1302 by the designated manufacturing facility/facilities that will receive the order if the user proceeds with order placement via the checkout element 1806. For instance, the price listed in the price region 1804 can be determined based on the particular punch configuration(s), particular die configuration(s), particular back gauge configuration(s), particular bend sequence configuration(s), particular machine selection configuration(s), and/or particular part orientation configuration(s) for performing the various bend steps/operations at the designated manufacturing facility/facilities to form the modified sheet metal part 1302 in a manner that avoids collisions or other manufacturing errors, as determined by the DFM processing as noted above.

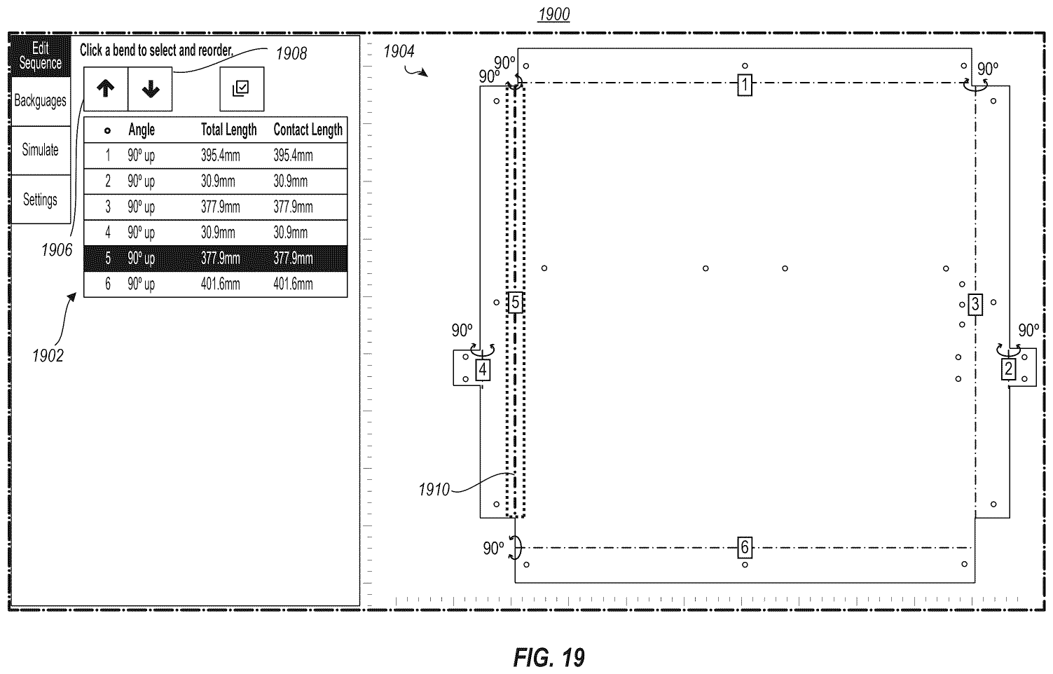

In some implementations, users may access or modify additional or alternative manufacturing configurations available to one or more designated manufacturing facilities (e.g., facilities configured to receive orders placed) for manufacturing custom sheet metal parts. FIGS. 19, 20, 21, and 22 illustrate additional manufacturing configurations that can be presented to users in association with a sheet metal part (e.g., represented in an input file, which can be provided by the user as discussed hereinabove with reference to FIG. 1) or a modified sheet metal part (e.g., generated based on material or characteristic selection or modification for an initially provided sheet metal part). In some implementations, additional manufacturing configurations similar to those shown and described with reference to FIGS. 19, 20, 21, and 22 are provided when specifically requested (e.g., for advanced users) or after an uploaded sheet metal part is determined to not be manufacturable via DFM processing. By presenting additional manufacturing configurations, users may receive additional information as to why a part is determined not to be manufacturable, which can allow users to experiment with different configurations to approach or achieve manufacturability, and/or which can inform user decisions with respect to redesigning a part for manufacturability.

FIG. 19 illustrates an example user interface display 1900 that includes a bend sequence configuration 1902 for manufacturing a sheet metal part 1904 (illustrated as a flat pattern in the user interface display 1900). The bend sequence configuration 1902 of the user interface display 1900 comprises a visualization of the ordering of bending operations (e.g., represented in the user interface display 1900 as individual list items of the bend sequence configuration 1902). The ordering can be selectively adjustable by a user (e.g., by providing user input at a system presenting the user interface display 1900). For instance, the user interface display 1900 includes ordering buttons 1906 and 1908, which may be selected to change the ordering of the bend sequence configuration 1902. By way of example, FIG. 19 illustrates the fifth bending operation of the bend sequence configuration 1902 in a highlighted or emphasized form, indicating that the fifth bending operation is in a selected state (e.g., the bend 1910 corresponding to the fifth bending operation is also emphasized in the custom sheet metal part 1904). With the fifth bending operation of the bend sequence configuration 1902 in the selected state, selection of the ordering buttons 1906 or 1908 can cause reordering of the bending operation. Other input modes for changing the ordering are within the scope of the present disclosure (e.g., drag and drop). In some instances, bending operations can be provided in the bend sequence configuration 1902 in a granular manner (e.g., with different bends along the same line being listed individually; enabling ordering of partial bends, etc.).

In the example bend sequence configuration 1902 of the user interface display 1900, the individual list items representing individual bend operations are associated with respective information, including order number (represented by the “#” symbol), bend angle, total length, and contact length. In some implementations, additional or alternative information is provided for each of the bending operations. For instance, the machine selection, punch, and/or die for each of the bending operations may be presented in the user interface display 1900 in association with each of the list items of the bend sequence configuration 1902, and such parameters may be selectively modifiable by users (in accordance with configurations available to the designated manufacturing facility/facilities).

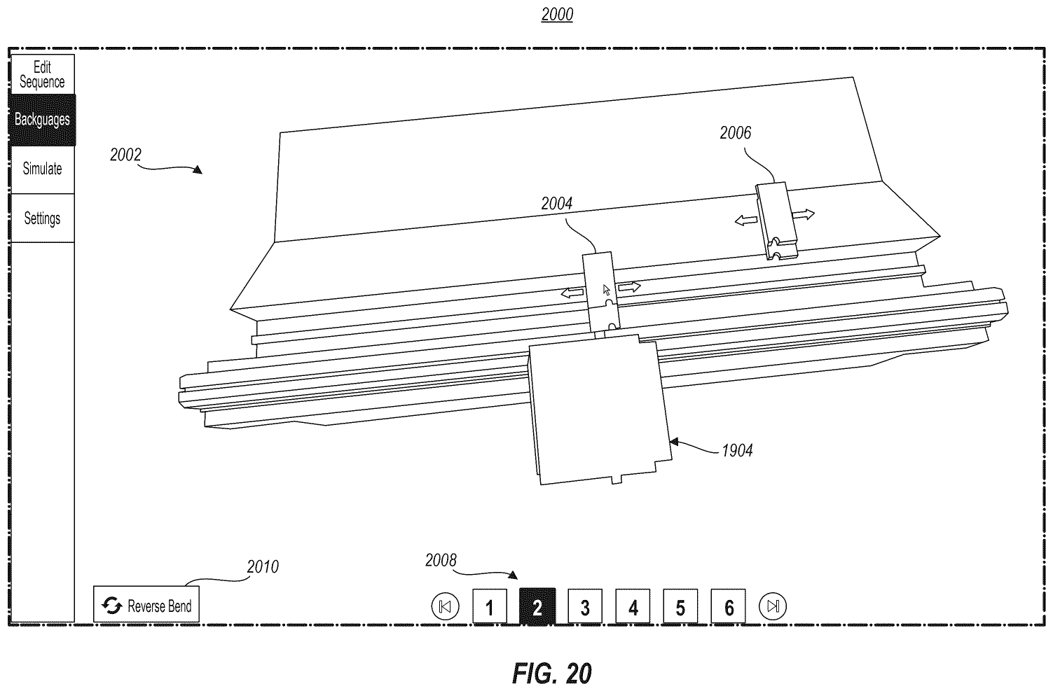

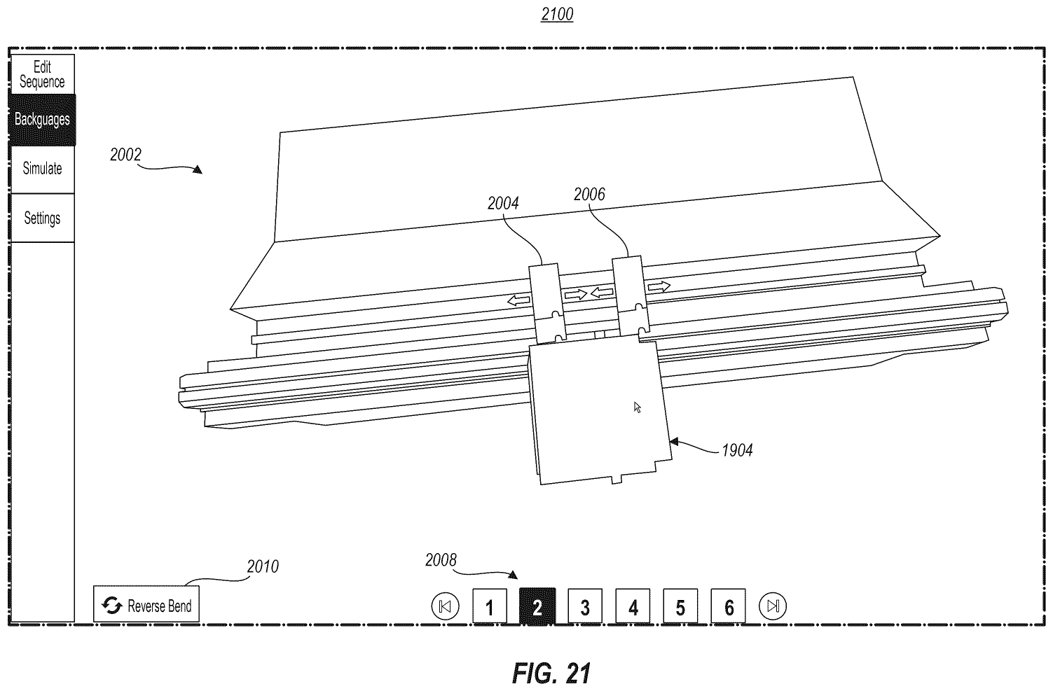

FIGS. 20 and 21 illustrate example user interface displays 2000 and 2100, respectively, that include a back gauge configuration 2002 for manufacturing the sheet metal part 1904. The back gauge configuration 2002 shown in FIGS. 20 and 21 comprises a visualization of the placement of back gauges 2004 and 2006 during bending operations (characteristics of the back gauges 2004 and 2006 may be defined by the machine selection discussed above with reference to FIG. 19). For instance, the user interface display 2000 and the user interface display 2100 show a bending operation index 2008 with numbered items corresponding to the different bending operations of the bend sequence configuration 1902 discussed hereinabove with reference to FIG. 19. Users may navigate to different bending operations via the bending operation index 2008 to access the back gauge configuration for the selected bending operation.

In FIGS. 20 and 21, the second bending operation of the bending operation index 2008 (corresponding to the second list item of the bend sequence configuration 1902) is selected for analysis, giving rise to the back gauge configuration 2002 shown in the user interface displays 2000 and 2100. The back gauge configuration 2002 shown in the user interface display 2000 provides an initial configuration of the back gauges 2004 and 2006 (e.g., a configuration selected via DFM processing, as described herein). A user may provide control input (e.g., click/tap and drag input, or other types) directed to the back gauges 2004 and/or 2006 within the user interface display 2000 to selectively change the configuration of the back gauges 2004 and/or 2006 for the second bending operation of the bending operation index 2008 (positional adjustment of the back gauges 2004 and 2006 may be guided by object snap functionality to assist users in aligning the back gauges 2004 and 2006 with the sheet metal part 1904). The back gauge configuration 2002 of the user interface display 2100 of FIG. 21 illustrates a modified position of the back gauges 2004 and 2006 with respect to the sheet metal part 1904 for the second bending operation, which may occur after user input is detected modifying the positioning of the back gauges 2004 and 2006 for the second bending operation.

The user interface displays 2000 and 2100 also include an orientation element 2010, which can be selectable by users to achieve changes in the orientation of the sheet metal part 1904 for the selected bending operation of the bending operation index 2008. For instance, selection of the orientation element 2010 can cause a 180 degree rotation of the sheet metal part 1904 about its out-of-plane axis or Z-axis within the user interface displays 2000 and/or 2100.

In accordance with the discussion of FIGS. 19, 20, and 21, a user may provide user input to define one or more aspects of a particular manufacturing configuration for individual bend operations for forming a sheet metal part 1904. The particular manufacturing configuration can include a particular bend sequence configuration 1902, machine selection configuration, punch configuration, die configuration, back gauge configuration 2002, and/or part orientation configuration for each of the bending operations. In some instances, the punch configuration and/or the die configuration available for selection are constrained by a bend angle and/or a bend radius selected via user input (as described herein with reference to FIGS. 11, 12, and 13). DFM processing may be performed using the particular manufacturing configuration to determine whether the sheet metal part 1904 is manufacturable using the particular manufacturing configuration (e.g., by applying virtual bending operations to a flat pattern based on the sheet metal part 1904 using the particular manufacturing configuration). Based on the outcome of the DFM processing, one or more indications of manufacturability may be presented to the user (e.g., similar to one or more of manufacturability indicators 302, 404, 502, 1004, 1602, 1702, and/or 1802). In some implementations, when the DFM processing indicates that the sheet metal part 1904 is manufacturable by the designated manufacturing facility/facilities, pricing information for manufacturing the sheet metal part 1904 can be automatically determined, updated, and/or presented, and/or order placement functionality for ordering manufacture of the sheet metal part 1904 from the designated manufacturing facility/facilities may be selectively enabled (e.g., similar to the user interface display 1800 of FIG. 18). In some instances, after an order is placed for manufacture of the sheet metal part 1904, the particular manufacturing configuration may be sent to the designated manufacturing facility/facilities along with the order, which may enable laborers to reference a working configuration for manufacturing the sheet metal part 1904.

In some instances, if the DFM processing indicates that the sheet metal part 1904 is not manufacturable by the designated manufacturing facility/facilities, an indication of non-manufacturability may be presented (e.g., similar to manufacturability indicators 302, 404, and/or 502), which may indicate one or more problem regions associated with manufacturing the 1904 using the particular manufacturing configuration.

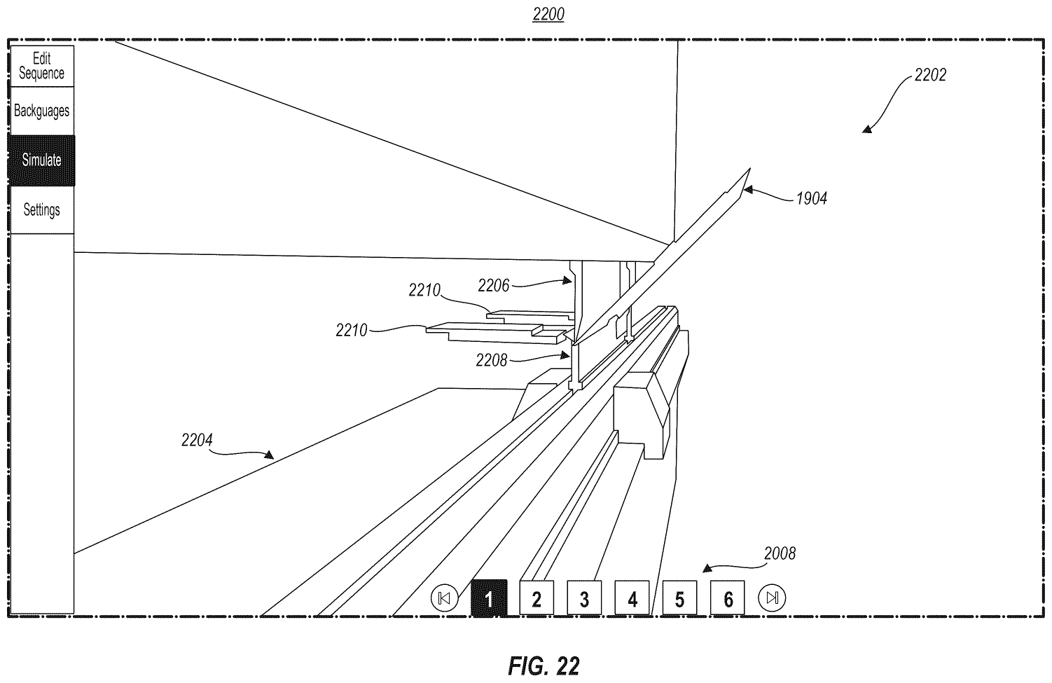

The virtual bending operations of the DFM processing using the particular manufacturing configuration may additionally be presented to the user. For instance, FIG. 22 illustrates an example user interface display 2200 that includes a manufacturing simulation 2202 for the sheet metal part 1904. The manufacturing simulation 2202 depicts a press brake machine 2204 with one or more punches 2206, dies 2208, and back gauges 2210 to facilitate formation of the sheet metal part 1904. The manufacturing simulation 2202 depicts operation of the press brake machine 2204 and its components to show bending operations for forming the sheet metal part 1904. In the example shown in FIG. 22, the user interface display 2200 also includes the bending operation index 2008 to indicate to the user which bending operation is being visually depicted. The press brake machine 2204 and one or more punches 2206, dies 2208, and back gauges 2210, as well as their configurations, shown in the manufacturing simulation 2202 can be determined by the user-defined particular manufacturing configuration discussed hereinabove with reference to FIGS. 19, 20, and 21 (recognizing that different press brake machines, punches, dies, back gauges, and/or configurations thereof can be used for different bending operations).

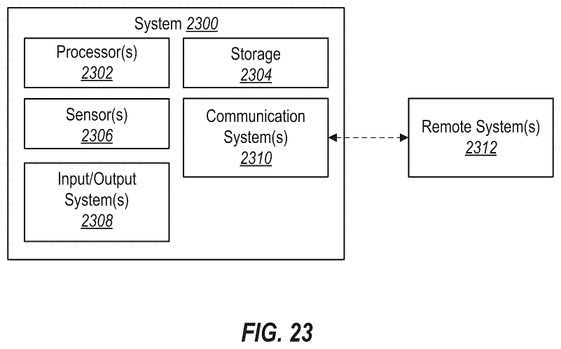

FIG. 23 illustrates example components of a system 2300 that may comprise or implement aspects of one or more disclosed embodiments. For example, FIG. 23 illustrates an implementation in which the system 2300 includes processor(s) 2302, storage 2304, sensor(s) 2306, I/O system(s) 2308, and communication system(s) 2310. Although FIG. 23 illustrates a system 2300 as including particular components, one will appreciate, in view of the present disclosure, that a system 2300 may comprise any number of additional or alternative components.

The processor(s) 2302 may comprise one or more sets of electronic circuitries that include any number of logic units, registers, and/or control units to facilitate the execution of computer-readable instructions (e.g., instructions that form a computer program). Such computer-readable instructions may be stored within storage 2304. The storage 2304 may comprise physical system memory and may be volatile, non-volatile, or some combination thereof. Furthermore, storage 2304 may comprise local storage, remote storage (e.g., accessible via communication system(s) 2310 or otherwise), or some combination thereof. Additional details related to processors (e.g., processor(s) 2302) and computer storage media (e.g., storage 2304) will be provided hereinafter.

As will be described in more detail, the processor(s) 2302 may be configured to execute instructions stored within storage 2304 to perform certain actions. In some instances, the actions may rely at least in part on communication system(s) 2310 for receiving data from remote system(s) 2312, which may include, for example, separate systems or computing devices, sensors, servers, and/or others. The communications system(s) 2310 may comprise any combination of software or hardware components that are operable to facilitate communication between on-system components/devices and/or with off-system components/devices. For example, the communications system(s) 2310 may comprise ports, buses, or other physical connection apparatuses for communicating with other devices/components. Additionally, or alternatively, the communications system(s) 2310 may comprise systems/components operable to communicate wirelessly with external systems and/or devices through any suitable communication channel(s), such as, by way of non-limiting example, Bluetooth, ultra-wideband, WLAN, infrared communication, and/or others.

FIG. 23 illustrates that a system 2300 may comprise or be in communication with sensor(s) 2306. Sensor(s) 2306 may comprise any device for capturing or measuring data representative of perceivable phenomenon. By way of non-limiting example, the sensor(s) 2306 may comprise one or more image sensors, microphones, thermometers, barometers, magnetometers, accelerometers, gyroscopes, and/or others.

Furthermore, FIG. 23 illustrates that a system 2300 may comprise or be in communication with I/O system(s) 2308. I/O system(s) 2308 may include any type of input or output device such as, by way of non-limiting example, a display, a touch screen, a mouse, a keyboard, a controller, and/or others, without limitation.

Disclosed embodiments may comprise or utilize a special purpose or general-purpose computer including computer hardware, as discussed in greater detail below. Disclosed embodiments also include physical and other computer-readable media for carrying or storing computer-executable instructions and/or data structures. Such computer-readable media can be any available media that can be accessed by a general-purpose or special-purpose computer system. Computer-readable media that store computer-executable instructions in the form of data are one or more “physical computer storage media” or “computer-readable recording media” or “hardware storage device(s).” Computer-readable media that merely carry computer-executable instructions without storing the computer-executable instructions are “transmission media.” Thus, by way of example and not limitation, the current embodiments can comprise at least two distinctly different kinds of computer-readable media: computer storage media and transmission media.

Computer storage media (aka “hardware storage device”) are computer-readable hardware storage devices, such as RAM, ROM, EEPROM, CD-ROM, solid state drives (“SSD”) that are based on RAM, Flash memory, phase-change memory (“PCM”), or other types of memory, or other optical disk storage, magnetic disk storage or other magnetic storage devices, or any other medium that can be used to store desired program code means in hardware in the form of computer-executable instructions, data, or data structures and that can be accessed by a general-purpose or special-purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmission media can include a network and/or data links which can be used to carry program code in the form of computer-executable instructions or data structures and which can be accessed by a general purpose or special purpose computer. Combinations of the above are also included within the scope of computer-readable media.

Further, upon reaching various computer system components, program code means in the form of computer-executable instructions or data structures can be transferred automatically from transmission computer-readable media to physical computer-readable storage media (or vice versa). For example, computer-executable instructions or data structures received over a network or data link can be buffered in RAM within a network interface module (e.g., a “NIC”), and then eventually transferred to computer system RAM and/or to less volatile computer-readable physical storage media at a computer system. Thus, computer-readable physical storage media can be included in computer system components that also (or even primarily) utilize transmission media.

Computer-executable instructions comprise, for example, instructions and data which cause a general-purpose computer, special purpose computer, or special purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Disclosed embodiments may comprise or utilize cloud computing. A cloud model can be composed of various characteristics (e.g., on-demand self-service, broad network access, resource pooling, rapid elasticity, measured service, etc.), service models (e.g., Software as a Service (“SaaS”), Platform as a Service (“PaaS”), Infrastructure as a Service (“IaaS”), and deployment models (e.g., private cloud, community cloud, public cloud, hybrid cloud, etc.).

Those skilled in the art will appreciate that at least some aspects of the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, wearable devices, and the like. The invention may also be practiced in distributed system environments where multiple computer systems (e.g., local and remote systems), which are linked through a network (either by hardwired data links, wireless data links, or by a combination of hardwired and wireless data links), perform tasks. In a distributed system environment, program modules may be located in local and/or remote memory storage devices.

Alternatively, or in addition, at least some of the functionality described herein can be performed, at least in part, by one or more hardware logic components. For example, and without limitation, illustrative types of hardware logic components that can be used include Field-programmable Gate Arrays (FPGAs), Program-specific Integrated Circuits (ASICs), Application-specific Standard Products (ASSPs), System-on-a-chip systems (SOCs), Complex Programmable Logic Devices (CPLDs), central processing units (CPUs), graphics processing units (GPUs), and/or others.

As used herein, the terms “executable module,” “executable component,” “component,” “module,” or “engine” can refer to hardware processing units or to software objects, routines, or methods that may be executed on one or more computer systems. The different components, modules, engines, and services described herein may be implemented as objects or processors that execute on one or more computer systems (e.g., as separate threads).

Embodiments disclosed herein can include those in the following numbered clauses:

Clause 1. A system for facilitating user-interactable design for manufacturability of sheet metal, the system comprising: one or more processors; and one or more computer-readable recording media that store instructions that are executable by the one or more processors to configure the system to: access an input file submitted by a user, the input file comprising a representation of a sheet metal part; determine manufacturability of the sheet metal part by applying one or more virtual bending operations to a flat pattern based on the sheet metal part, wherein the one or more virtual bending operations are performed in accordance with manufacturing configurations available to one or more manufacturing facilities; cause presentation of an indication of manufacturability of the sheet metal part within a user interface; cause presentation of one or more sheet metal part characteristics within the user interface that enables user selection or modification of the one or more sheet metal part characteristics for the sheet metal part, wherein the one or more sheet metal part characteristics comprise bend radius or bend angle for one or more bends of the sheet metal part; generate a modified sheet metal part by modifying the sheet metal part based on user selection or modification of at least one of the one or more sheet metal part characteristics at the user interface; determine manufacturability of the modified sheet metal part by applying one or more second virtual bending operations to a modified flat pattern based on the modified sheet metal part, wherein the one or more second virtual bending operations are performed in accordance with the manufacturing configurations available to the one or more manufacturing facilities; cause presentation of an indication of manufacturability of the modified sheet metal part within the user interface; and in response to determining that the modified sheet metal part is manufacturable with particular manufacturing configurations available to the one or more manufacturing facilities: automatically determine or update a price of manufacturing the modified sheet metal part based on the particular manufacturing configurations; cause presentation of the price of manufacturing the modified sheet metal part within the user interface; and selectively enable order placement functionality within the user interface that triggers manufacturing of the modified sheet metal part at the one or more manufacturing facilities.

Clause 2. The system of clause 1, wherein the input file comprises a 3D model file or a 2D drawing file.

Clause 3. The system of clause 1, wherein the input file comprises a 3D model file, and wherein the flat pattern based on the sheet metal part is obtained by applying one or more virtual inverse bending operations to the sheet metal part as represented in the 3D model file.

Clause 4. The system of clause 1, wherein determining manufacturability of sheet metal part comprises iteratively applying virtual bending operations to the flat pattern using different manufacturing configurations.

Clause 5. The system of clause 1, wherein the manufacturing configurations available to the one or more manufacturing facilities comprise one or more punch configurations, one or more die configurations, one or more back gauge configurations, one or more bend sequence configurations, one or more machine selection configurations, or one or more part orientation configurations.

Clause 6. The system of clause 1, wherein, when the sheet metal part is not manufacturable, the indication of manufacturability of the sheet metal part indicates one or more problem regions associated with the sheet metal part.

Clause 7. The system of clause 1, wherein the instructions are executable by the one or more processors to configure the system to cause presentation of the one or more sheet metal part characteristics in response to determining that the sheet metal part is not manufacturable.

Clause 8. The system of clause 1, wherein user selection or modification of the bend angle for one or more bends of the sheet metal part causes selection of one or more punch configurations for the one or more second virtual bending operations.

Clause 9. The system of clause 1, wherein the presentation of the bend radius for one or more bends enables users to manually select a bend radius or trigger automatic selection of a bend radius.

Clause 10. The system of clause 9, wherein bend radius options presented for manual selection are constrained by the manufacturing configurations available at the one or more manufacturing facilities.

Clause 11. The system of clause 1, wherein user selection or modification of the bend radius for one or more bends of the sheet metal part causes selection of one or more die configurations for the one or more second virtual bending operations.

Clause 12. The system of clause 1, wherein the instructions are executable by the one or more processors to configure the system to cause presentation of a representation of the modified sheet metal part or the modified flat pattern within the user interface.

Clause 13. The system of clause 12, wherein the representation of the modified flat pattern depicts die contact area for one or more bends of the modified flat pattern.

Clause 14. The system of clause 1, wherein determining manufacturability of the modified sheet metal part comprises iteratively applying second virtual bend operations to the modified flat pattern using different manufacturing configurations.

Clause 15. The system of clause 1, wherein the particular manufacturing configurations comprise a particular punch configuration, a particular die configuration, a particular back gauge configuration, a particular bend sequence configuration, a particular machine selection configuration, or a particular part orientation configuration.

Clause 16. The system of clause 1, wherein determining manufacturability of the modified sheet metal part comprises determining a set of manufacturing configurations that minimizes collisions between the modified sheet metal part and one or more manufacturing components.

Clause 17. The system of clause 16, wherein, in response to determining that the modified sheet metal part is not manufacturable, the presentation of the indication of manufacturability of the modified sheet metal part indicates one or more collision regions associated with the modified sheet metal part.

Clause 18. The system of clause 1, wherein the instructions are executable by the one or more processors to configure the system to cause alternate or simultaneous presentation of the modified sheet metal part and the sheet metal part within the user interface.

Clause 19. The system of clause 1, wherein the instructions are executable by the one or more processors to configure the system to cause, within the user interface, presentation of a simulation of manufacturing the sheet metal part or the modified sheet metal part using manufacturing configurations available to the one or more manufacturing facilities.

Clause 20. The system of clause 19, wherein the simulation of manufacturing the modified sheet metal part uses (i) one or more punch configurations selected based on user selection or modification of the bend angle for one or more bends or (ii) one or more die configurations selected based on user selection or modification of the bend radius for one or more bends.

Clause 21. A system for facilitating user-interactable design for manufacturability of sheet metal, the system comprising: one or more processors; and one or more computer-readable recording media that store instructions that are executable by the one or more processors to configure the system to: access an input file submitted by a user, the input file comprising a representation of a sheet metal part; cause presentation of one or more sheet metal part characteristics within a user interface that enables user selection or modification of the one or more sheet metal part characteristics for the sheet metal part, wherein the one or more sheet metal part characteristics comprise bend radius or bend angle for one or more bends of the sheet metal part; generate a modified sheet metal part by modifying the sheet metal part based on user selection or modification of at least one of the one or more sheet metal part characteristics at the user interface; determine manufacturability of the modified sheet metal part by applying one or more virtual bending operations to a modified flat pattern based on the modified sheet metal part, wherein the one or more virtual bending operations are performed in accordance with manufacturing configurations available to one or more manufacturing facilities; and in response to determining that the modified sheet metal part is manufacturable with particular manufacturing configurations available to the one or more manufacturing facilities: automatically determine or update a price of manufacturing the modified sheet metal part based on the particular manufacturing configurations; cause presentation of the price of manufacturing the modified sheet metal part within the user interface; and selectively enable order placement functionality within the user interface that triggers manufacturing of the modified sheet metal part at the one or more manufacturing facilities.

Clause 22. The system of clause 21, wherein the input file comprises a 3D model file or a 2D drawing file.

Clause 23. The system of clause 21, wherein the manufacturing configurations available to the one or more manufacturing facilities comprise one or more punch configurations, one or more die configurations, one or more back gauge configurations, one or more bend sequence configurations, one or more machine selection configurations, or one or more part orientation configurations.

Clause 24. The system of clause 21, wherein user selection or modification of the bend angle for one or more bends of the sheet metal part causes selection of one or more punch configurations for the one or more virtual bending operations.

Clause 25. The system of clause 21, wherein the presentation of the bend radius for one or more bends enables users to manually select a bend radius or trigger automatic selection of a bend radius.

Clause 26. The system of clause 25, wherein bend radius options presented for manual selection are constrained by the manufacturing configurations available at the one or more manufacturing facilities.

Clause 27. The system of clause 21, wherein user selection or modification of the bend radius for one or more bends of the sheet metal part causes selection of one or more die configurations for the one or more virtual bending operations.

Clause 28. The system of clause 21, wherein the instructions are executable by the one or more processors to configure the system to cause presentation of a representation of the modified sheet metal part or the modified flat pattern.

Clause 29. The system of clause 28, wherein the representation of the modified flat pattern depicts die contact area for one or more bends of the modified flat pattern.

Clause 30. The system of clause 21, wherein determining manufacturability of the modified sheet metal part comprises iteratively applying virtual bend operations to the modified flat pattern using different manufacturing configurations.

Clause 31. The system of clause 21, wherein the particular manufacturing configurations comprise a particular punch configuration, a particular die configuration, a particular back gauge configuration, a particular bend sequence configuration, a particular machine selection configuration, or a particular part orientation configuration.

Clause 32. The system of clause 21, wherein determining manufacturability of the modified sheet metal part comprises determining a set of manufacturing configurations that minimizes collisions between the modified sheet metal part and one or more manufacturing components.

Clause 33. The system of clause 32, wherein the instructions are executable by the one or more processors to configure the system to, in response to determining that the modified sheet metal part is not manufacturable, cause presentation of an indication of non-manufacturability of the modified sheet metal part that indicates one or more problem regions associated with the modified sheet metal part.

Clause 34. The system of clause 21, wherein the instructions are executable by the one or more processors to configure the system to cause, within the user interface, presentation of a simulation of manufacturing the modified sheet metal part using manufacturing configurations available to the one or more manufacturing facilities.

Clause 35. The system of clause 34, wherein the simulation of manufacturing the modified sheet metal part uses (i) one or more punch configurations selected based on user selection or modification of the bend angle for one or more bends or (ii) one or more die configurations selected based on user selection or modification of the bend radius for one or more bends.

Clause 36. A system for facilitating user-interactable design for manufacturability of sheet metal, the system comprising: one or more processors; and one or more computer-readable recording media that store instructions that are executable by the one or more processors to configure the system to: access an input file submitted by a user, the input file comprising a representation of a sheet metal part; cause, within a user interface, presentation of one or more manufacturing configurations available to one or more manufacturing facilities for manufacturing the sheet metal part or a modified sheet metal part based on the sheet metal part, wherein the presentation enables user selection or modification of the one or more manufacturing configurations, wherein the one or more manufacturing configurations comprise one or more punch configurations, one or more die configurations, one or more back gauge configurations, one or more bend sequence configurations, one or more machine selection configurations, or one or more part orientation configurations; determine manufacturability of the sheet metal part or the modified sheet metal part by applying one or more virtual bending operations to a flat pattern based on the sheet metal part or the modified sheet metal part, wherein the one or more virtual bending operations are performed based on particular manufacturing configurations obtained by user selection or modification of the one or more manufacturing configurations; and in response to determining that the sheet metal part or the modified sheet metal part is manufacturable with the particular manufacturing configurations: automatically determine or update a price of manufacturing the sheet metal part or the modified sheet metal part based on the particular manufacturing configurations; cause presentation of the price of manufacturing the sheet metal part or the modified sheet metal part within the user interface; and selectively enable order placement functionality within the user interface that triggers manufacturing of the sheet metal part or the modified sheet metal part at the one or more manufacturing facilities.

Clause 37. The system of clause 36, wherein the input file comprises a 3D model file or a 2D drawing file.

Clause 38. The system of clause 36, wherein the presentation of the one or more bend sequence configurations comprises a visualization of ordering of one or more bending operations, wherein the ordering is selectively adjustable by the user.

Clause 39. The system of clause 36, wherein the presentation of the one or more back gauge configurations comprises a visualization of placement of one or more back gauges during one or more bending operations, wherein the placement of the one or more back gauges is selectively adjustable by the user.

Clause 40. The system of clause 36, wherein the particular manufacturing configurations comprise a particular punch configuration, a particular die configuration, a particular back gauge configuration, a particular bend sequence configuration, a particular machine selection configuration, or a particular part orientation configuration.

Clause 41. The system of clause 36, wherein the instructions are executable by the one or more processors to configure the system to, in response to determining that the sheet metal part or the modified sheet metal part is not manufacturable, cause presentation of an indication of non-manufacturability of the sheet metal part or the modified sheet metal part that indicates one or more collision regions associated with the sheet metal part or the modified sheet metal part.

Clause 42. The system of clause 36, wherein the instructions are executable by the one or more processors to configure the system to cause, within the user interface, presentation of a simulation of manufacturing the sheet metal part or the modified sheet metal part using the particular manufacturing configurations.

Clause 43. The system of clause 36, wherein the instructions are executable by the one or more processors to configure the system to send the particular manufacturing configurations to the one or more manufacturing facilities in association with the sheet metal part or the modified sheet metal part.

One will also appreciate how any feature or operation disclosed herein may be combined with any one or combination of the other features and operations disclosed herein. Additionally, the content or feature in any one of the figures may be combined or used in connection with any content or feature used in any of the other figures. In this regard, the content disclosed in any one figure is not mutually exclusive and instead may be combinable with the content from any of the other figures.

The present invention may be embodied in other specific forms without departing from its spirit or characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is currently claimed is:

1. A system for facilitating user-interactable design for manufacturability of sheet metal, the system comprising:
one or more processors; and
one or more computer-readable recording media that store instructions that are executable by the one or more processors to configure the system to:
access an input file submitted by a user, the input file comprising a representation of a sheet metal part;
determine manufacturability of the sheet metal part by applying one or more virtual bending operations to a flat pattern based on the sheet metal part, wherein the one or more virtual bending operations are performed in accordance with manufacturing configurations available to one or more manufacturing facilities;
cause presentation of an indication of manufacturability of the sheet metal part within a user interface;
cause presentation of one or more sheet metal part characteristics within the user interface that enables user selection or modification of the one or more sheet metal part characteristics for the sheet metal part, wherein the one or more sheet metal part characteristics comprise bend radius or bend angle for one or more bends of the sheet metal part;
generate a modified sheet metal part by modifying the sheet metal part based on user selection or modification of at least one of the one or more sheet metal part characteristics at the user interface;
determine manufacturability of the modified sheet metal part by applying one or more second virtual bending operations to a modified flat pattern based on the modified sheet metal part, wherein the one or more second virtual bending operations are performed in accordance with the manufacturing configurations available to the one or more manufacturing facilities;
cause presentation of an indication of manufacturability of the modified sheet metal part within the user interface; and
in response to determining that the modified sheet metal part is manufacturable with particular manufacturing configurations available to the one or more manufacturing facilities:
automatically determine or update a price of manufacturing the modified sheet metal part based on the particular manufacturing configurations;
cause presentation of the price of manufacturing the modified sheet metal part within the user interface; and
selectively enable order placement functionality within the user interface that triggers manufacturing of the modified sheet metal part at the one or more manufacturing facilities.

2. The system of claim 1, wherein the input file comprises a 3D model file, and wherein the flat pattern based on the sheet metal part is obtained by applying one or more virtual inverse bending operations to the sheet metal part as represented in the 3D model file.

3. The system of claim 1, wherein determining manufacturability of sheet metal part comprises iteratively applying virtual bending operations to the flat pattern using different manufacturing configurations.

4. The system of claim 1, wherein the manufacturing configurations available to the one or more manufacturing facilities comprise one or more punch configurations, one or more die configurations, one or more back gauge configurations, one or more bend sequence configurations, one or more machine selection configurations, or one or more part orientation configurations.

5. The system of claim 1, wherein, when the sheet metal part is not manufacturable, the indication of manufacturability of the sheet metal part indicates one or more problem regions associated with the sheet metal part.

6. The system of claim 1, wherein the instructions are executable by the one or more processors to configure the system to cause presentation of the one or more sheet metal part characteristics in response to determining that the sheet metal part is not manufacturable.

7. The system of claim 1, wherein user selection or modification of the bend angle for one or more bends of the sheet metal part causes selection of one or more punch configurations for the one or more second virtual bending operations.

8. The system of claim 1, wherein the presentation of the bend radius for one or more bends enables users to manually select a bend radius or trigger automatic selection of a bend radius.

9. The system of claim 8, wherein bend radius options presented for manual selection are constrained by the manufacturing configurations available at the one or more manufacturing facilities.

10. The system of claim 1, wherein user selection or modification of the bend radius for one or more bends of the sheet metal part causes selection of one or more die configurations for the one or more second virtual bending operations.

11. The system of claim 1, wherein the instructions are executable by the one or more processors to configure the system to cause alternate or simultaneous presentation of the modified sheet metal part and the sheet metal part within the user interface.

12. The system of claim 1, wherein the instructions are executable by the one or more processors to configure the system to cause, within the user interface, presentation of a simulation of manufacturing the sheet metal part or the modified sheet metal part using manufacturing configurations available to the one or more manufacturing facilities.

13. The system of claim 12, wherein the simulation of manufacturing the modified sheet metal part uses (i) one or more punch configurations selected based on user selection or modification of the bend angle for one or more bends or (ii) one or more die configurations selected based on user selection or modification of the bend radius for one or more bends.

14. A system for facilitating user-interactable design for manufacturability of sheet metal, the system comprising:
one or more processors; and
one or more computer-readable recording media that store instructions that are executable by the one or more processors to configure the system to:
access an input file submitted by a user, the input file comprising a representation of a sheet metal part;
cause presentation of one or more sheet metal part characteristics within a user interface that enables user selection or modification of the one or more sheet metal part characteristics for the sheet metal part, wherein the one or more sheet metal part characteristics comprise bend radius or bend angle for one or more bends of the sheet metal part;
generate a modified sheet metal part by modifying the sheet metal part based on user selection or modification of at least one of the one or more sheet metal part characteristics at the user interface;
determine manufacturability of the modified sheet metal part by applying one or more virtual bending operations to a modified flat pattern based on the modified sheet metal part, wherein the one or more virtual bending operations are performed in accordance with manufacturing configurations available to one or more manufacturing facilities; and
in response to determining that the modified sheet metal part is manufacturable with particular manufacturing configurations available to the one or more manufacturing facilities:
automatically determine or update a price of manufacturing the modified sheet metal part based on the particular manufacturing configurations;
cause presentation of the price of manufacturing the modified sheet metal part within the user interface; and
selectively enable order placement functionality within the user interface that triggers manufacturing of the modified sheet metal part at the one or more manufacturing facilities.

15. The system of claim 14, wherein the instructions are executable by the one or more processors to configure the system to cause presentation of a representation of the modified sheet metal part or the modified flat pattern, wherein the representation of the modified flat pattern depicts die contact area for one or more bends of the modified flat pattern.

16. The system of claim 14, wherein determining manufacturability of the modified sheet metal part comprises iteratively applying virtual bend operations to the modified flat pattern using different manufacturing configurations.

17. The system of claim 14, wherein the particular manufacturing configurations comprise a particular punch configuration, a particular die configuration, a particular back gauge configuration, a particular bend sequence configuration, a particular machine selection configuration, or a particular part orientation configuration.

18. The system of claim 14, wherein determining manufacturability of the modified sheet metal part comprises determining a set of manufacturing configurations that minimizes collisions between the modified sheet metal part and one or more manufacturing components.

19. The system of claim 18, wherein the instructions are executable by the one or more processors to configure the system to, in response to determining that the modified sheet metal part is not manufacturable, cause presentation of an indication of non-manufacturability of the modified sheet metal part that indicates one or more problem regions associated with the modified sheet metal part.

20. A system for facilitating user-interactable design for manufacturability of sheet metal, the system comprising:
one or more processors; and
one or more computer-readable recording media that store instructions that are executable by the one or more processors to configure the system to:
access an input file submitted by a user, the input file comprising a representation of a sheet metal part;
cause, within a user interface, presentation of one or more manufacturing configurations available to one or more manufacturing facilities for manufacturing the sheet metal part or a modified sheet metal part based on the sheet metal part, wherein the presentation enables user selection or modification of the one or more manufacturing configurations, wherein the one or more manufacturing configurations comprise one or more punch configurations, one or more die configurations, one or more back gauge configurations, one or more bend sequence configurations, one or more machine selection configurations, or one or more part orientation configurations;
determine manufacturability of the sheet metal part or the modified sheet metal part by applying one or more virtual bending operations to a flat pattern based on the sheet metal part or the modified sheet metal part, wherein the one or more virtual bending operations are performed based on particular manufacturing configurations obtained by user selection or modification of the one or more manufacturing configurations; and
in response to determining that the sheet metal part or the modified sheet metal part is manufacturable with the particular manufacturing configurations:
automatically determine or update a price of manufacturing the sheet metal part or the modified sheet metal part based on the particular manufacturing configurations;
cause presentation of the price of manufacturing the sheet metal part or the modified sheet metal part within the user interface; and
selectively enable order placement functionality within the user interface that triggers manufacturing of the sheet metal part or the modified sheet metal part at the one or more manufacturing facilities.
